(19) United States
(12) Patent Application Publication
(10) Pub. No.: US 2018/0308839 A1
(43) Pub. Date: Oct. 25, 2018

(54) SEMICONDUCTOR DEVICE AND METHOD OF MANUFACTURING THE SAME

(71) Applicant: Renesas Electronics Corporation, Tokyo (JP)

(72) Inventor: Yukio TAKAHASHI, Hitachinaka-shi (JP)

(73) Assignee: Renesas Electronics Corporation, Tokyo (JP)

(21) Appl. No.: 15/904,634

(22) Filed: Feb. 26, 2018

(30) Foreign Application Priority Data
Apr. 21, 2017 (JP) 2017-084472

(51) Int. Cl. H01L 27/06; H01L 29/08; H01L 29/739; H01L 29/861

(52) U.S. Cl. CPC H01L 27/0664; H01L 29/861; H01L 29/7397; H01L 29/0804

(57) ABSTRACT

A semiconductor device and a method of manufacturing the same are provided so as to suppress an increase in the forward voltage of a first diode even if a driving signal is inputted to the gate electrode of an insulating gate bipolar transistor. An IGBT has a p-type body region. An anode region of the first diode has the same impurity region as the p-type body region of the IGBT. An anode region of a second diode is surrounded by an emitter groove and thus the anode region is separated from the p-type body region of the IGBT by the emitter groove.

### CROSS-REFERENCE TO RELATED APPLICATIONS

The disclosure of Japanese Patent Application No. 2017-084472 filed on Apr. 21, 2017 including the specification, drawings and abstract is incorporated herein by reference in its entirety.

The present invention relates to a semiconductor device and a method of manufacturing the same.

### BACKGROUND

Trench gate insulated-gate bipolar transistors (IGBTs) are widely used with low on resistances. Such IGBTs have been developed as reverse conducting semiconductor elements (RC-IGBT elements) in which IGBTs and free wheeling diodes (FWDs) are configured on the same semiconductor substrate. It is known that the RC-IGBTs are mounted in, for example, an inverter circuit and control a load according to pulse width modulation (PWM).

For RC-IGBTs, IE trench gate IGBT structures with an injection enhancement (IE) effect in conductivity modulation have been used to obtain a low on voltage with a low loss. In such an IE trench gate IGBT, a cell formation region includes active cell regions and inactive cell regions that are arranged alternately or like comb teeth. The active cell region is coupled to an emitter electrode and the inactive cell region includes a floating region. With this configuration, holes are hardly ejected from an emitter electrode when the IGBT is turned on. Thus, holes are easily accumulated in a drift region, achieving an IE effect in conductivity modulation.

Such IE trench gate IGBTs are disclosed in, for example, Japanese Unexamined Patent Application Publication No. 2012-256839 and Japanese Unexamined Patent Application Publication No. 2013-140885.

Japanese Unexamined Patent Application Publication No. 2012-256839 discloses a technique in which each linear-unit cell region provided in a cell formation region includes a linear active-cell region and linear inactive-cell regions with the linear active-cell region interposed between the linear inactive-cell regions.

Japanese Unexamined Patent Application Publication No. 2013-140885 discloses a technique in which each linear-unit cell region provided in a cell formation region has first and second linear-unit cell regions, the first linear-unit cell region having a linear active-cell region, the second linear-unit cell region having a linear-hole collector cell region.

### SUMMARY

In the case of an RC-IGBT installed in an inverter circuit, a driving signal inputted to the gate electrode of the IGBT is basically a signal phase-inverted relative to upper and lower arms. Thus, a driving signal is inputted to the gate electrode of an IGBT also in, for example, a freewheel operation of an FWD. In other words, an FWD operation and an IGBT operation occur at the same time.

In this case, the anode electrode of the FWD and the emitter electrode of the IGBT serve as common electrodes; meanwhile, the cathode electrode of the FWD and the collector electrode of the IGBT serve as common electrodes. Since the electrodes of the FWD and the IGBT serve as common electrodes, the anode and the cathode of the FWD tend to have the same potential when the gate of the IGBT is turned on during an operation of the FWD. Specifically, a part opposed to the gate electrode of a p-type channel layer is inverted to n-type so as to couple an n-type emitter layer to an n-type drift layer via an n-type layer, encouraging the p-type channel layer to have the same potential as the n-type drift layer. This suppresses a forward operation of the FWD. Hence, in a state where a driving signal is inputted to the gate electrode of the IGBT, a forward voltage Vf of the FWD rises so as to disadvantageously increase the switching loss of a semiconductor device.

Other problems and new characteristics will be clarified by a description of the present specification and the accompanying drawings.

A semiconductor device according to an embodiment includes a semiconductor substrate, an emitter groove electrode, an insulating gate bipolar transistor, a first diode, a second diode, a cathode region of a second conductivity type, and a first electrode. The semiconductor substrate has a first major surface, a second major surface opposite from the first major surface, and an emitter groove surrounding an anode formation region on the first major surface. The emitter groove electrode is embedded in the emitter groove. The insulating gate bipolar transistor has a body region of a first conductivity type on the semiconductor substrate, an emitter region of the second conductivity type, the emitter region being arranged on the body region and near the first major surface so as to be electrically coupled to the emitter groove electrode, and a collector region of the first conductivity type, the collector region being arranged on the body region and near the second major surface. The first diode has a first anode region of the first conductivity type, the first anode region including the same impurity region as the body region. The second diode has a second anode region of the first conductivity type, the second anode region being arranged on the anode formation region so as to be separated from the first anode region by the emitter groove. The cathode region is arranged on the second major surface so as to act as a cathode for each of the first diode and the second diode. The first electrode is arranged on the second major surface and is in contact with the collector region and the cathode region.

A semiconductor device according to another embodiment includes a semiconductor substrate, an insulating gate bipolar transistor, a first diode, a second diode, a cathode region of a second conductivity type, and a first electrode. The semiconductor substrate has a first major surface, a second major surface opposite from the first major surface, and a gate groove surrounding an anode formation region on the first major surface. The insulating gate bipolar transistor has a body region of a first conductivity type on the semiconductor substrate, an emitter region of the second conductivity type, the emitter region being arranged on the body region and near the first major surface, a collector region of the first conductivity type, the collector region being arranged on the body region and near the second major surface, and a gate electrode embedded in the gate groove. The first diode has a first anode region of the first conductivity type, the first anode region including the same impurity region as the body region. The second diode has a second anode region of the first conductivity type, the second anode region being arranged on the anode formation region so as to be separated from the first anode region by the emitter gate groove. The cathode region is arranged on the second major surface so as to act as a cathode for each of the first diode and the second diode. The first electrode is arranged on the second major surface and is in contact with the collector region and the cathode region.

A method of manufacturing the semiconductor device according to the embodiment includes the following steps:

The semiconductor substrate is prepared that has the first major surface, the second major surface opposite from the first major surface, and the emitter groove surrounding the anode formation region on the first major surface. The emitter groove electrode is formed so as to be embedded in the emitter groove. The insulating gate bipolar transistor is formed that includes the body region of the first conductivity type on the semiconductor substrate, the emitter region of the second conductivity type, the emitter region being arranged on the body region and near the first major surface so as to be electrically coupled to the emitter groove electrode, and the collector region of the first conductivity type, the collector region being arranged on the body region and near the second major surface. The first anode region of the first conductivity type is formed such that the first anode region includes the same impurity region as the body region. The second anode region of the first conductivity type is formed so as to be arranged on the anode formation region and separated from the first anode region by the emitter groove electrode. The cathode region of the second conductivity type is formed on the second major surface so as to include the first diode with the first anode region and include the second diode with the second anode region. The electrode is formed so as to be arranged on the second major surface and in contact with the collector region and the cathode region.

The foregoing embodiments can suppress an increase in the forward voltage of the first diode even if a driving signal is inputted to the gate electrode of the insulating gate bipolar transistor.

### BRIEF DESCRIPTION OF THE DRAWINGS

FIG. 1 is a plan view of a semiconductor chip acting as a semiconductor device according to a first embodiment;

FIG. 2 is a plan view showing the principal part of the semiconductor device according to the first embodiment;

FIG. 3 is a plan view showing the principal part of the semiconductor device according to the first embodiment and an enlarged view of a region AR3 surrounded by a chain double-dashed line in FIG. 2;

FIG. 4 is a cross-sectional view taken along line IV-IV of FIG. 3;

FIG. 5 is a cross-sectional view taken along line V-V of FIG. 3;

FIG. 6 is a bottom view showing the distribution of a p-type collector region and n-type cathode regions on the second major surface of a semiconductor substrate;

FIG. 7 is a circuit diagram showing the circuit configuration of the semiconductor device according to the first embodiment;

FIG. 8 is a cross-sectional view showing a first step of a method of manufacturing the semiconductor device according to the first embodiment;

FIG. 9 is a cross-sectional view showing a second step of the method of manufacturing the semiconductor device according to the first embodiment;

FIG. 10 is a cross-sectional view showing a third step of the method of manufacturing the semiconductor device according to the first embodiment;

FIG. 11 is a cross-sectional view showing a fourth step of the method of manufacturing the semiconductor device according to the first embodiment;

FIG. 12 is a cross-sectional view showing a fifth step of the method of manufacturing the semiconductor device according to the first embodiment;

FIG. 13 is a cross-sectional view showing a sixth step of the method of manufacturing the semiconductor device according to the first embodiment;

FIG. 14 is a cross-sectional view showing a seventh step of the method of manufacturing the semiconductor device according to the first embodiment;

FIG. 15 is a cross-sectional view showing an eighth step of the method of manufacturing the semiconductor device according to the first embodiment;

FIG. 16 is a cross-sectional view showing a ninth step of the method of manufacturing the semiconductor device according to the first embodiment;

FIG. 17 is a cross-sectional view showing a tenth step of the method of manufacturing the semiconductor device according to the first embodiment;

FIG. 18 is a cross-sectional view showing an eleventh step of the method of manufacturing the semiconductor device according to the first embodiment;

FIG. 19 is a cross-sectional view showing a twelfth step of the method of manufacturing the semiconductor device according to the first embodiment;

FIG. 20 is a cross-sectional view showing a thirteenth step of the method of manufacturing the semiconductor device according to the first embodiment;

FIG. 21 is a cross-sectional view showing a fourteenth step of the method of manufacturing the semiconductor device according to the first embodiment;

FIG. 22 is a cross-sectional view showing a fifteenth step of the method of manufacturing the semiconductor device according to the first embodiment;

FIG. 23 is a cross-sectional view showing a sixteenth step of the method of manufacturing the semiconductor device according to the first embodiment;

FIG. 24 is a cross-sectional view showing a seventeenth step of the method of manufacturing the semiconductor device according to the first embodiment;

FIG. 25 is a cross-sectional view showing an eighteenth step of the method of manufacturing the semiconductor device according to the first embodiment;

FIG. 26 is a cross-sectional view showing a nineteenth step of the method of manufacturing the semiconductor device according to the first embodiment;

FIG. 27 is a cross-sectional view showing a twentieth step of the method of manufacturing the semiconductor device according to the first embodiment;

FIG. 28 is a cross-sectional view showing a twenty-first step of the method of manufacturing the semiconductor device according to the first embodiment;

FIG. 29 is a plan view showing the principal part of the semiconductor device according to a first improvement example of the first embodiment;

FIG. 30 is a cross-sectional view taken along line XXX-XXX of FIG. 29;

FIG. 31 is a cross-sectional view showing the configuration of the semiconductor device according to a second improvement example of the first embodiment, that is, a cross-sectional view taken along line XXXI-XXXI of FIG. 29;

FIG. 32 is a cross-sectional view showing the configuration of the semiconductor device according to the second improvement example of the first embodiment, that is, a cross-sectional view taken along line XXX-XXX of FIG. 29;

FIG. 33 is a plan view showing the principal part of a semiconductor device according to a second embodiment;

FIG. 34 is a cross-sectional view taken along line XXXIV-XXXIV of FIG. 33;

FIG. 35 is a cross-sectional view taken along line XXXV-XXXV of FIG. 33;

FIG. 36 is a cross-sectional view taken along line XXXVI-XXXVI of FIG. 33;

FIG. 37 is a plan view showing the principal part of the semiconductor device according a first improvement example of the second embodiment;

FIG. 38 is a cross-sectional view taken along line XXXVIII-XXXVIII of FIG. 37;

FIG. 39 is a cross-sectional view taken along line XXXIX-XXXIX of FIG. 37;

FIG. 40 is a cross-sectional view taken along line XL-XL of FIG. 37;

FIG. 41 is a plan view showing the principal part of the semiconductor device according a second improvement example of the second embodiment;

FIG. 42 is a cross-sectional view taken along line XLII-XLII of FIG. 41;

FIG. 43 is a plan view showing the principal part of the semiconductor device according a third improvement example of the second embodiment;

FIG. 44 is a cross-sectional view taken along line XLIV-XLIV of FIG. 43;

FIG. 45 is a plan view showing the principal part of the semiconductor device according a fourth improvement example of the second embodiment;

FIG. 46 is a cross-sectional view taken along line XLVI-XLVI of FIG. 45;

FIG. 47 is a plan view showing the principal part of the semiconductor device according a fifth improvement example of the second embodiment;

FIG. 48 is a cross-sectional view taken along line XLVIII-XLVIII of FIG. 47;

FIG. 49 is a cross-sectional view showing a first configuration according to a first modification of the first embodiment;

FIG. 50 is a cross-sectional view showing a second configuration according to the first modification of the first embodiment;

FIG. 51 is a cross-sectional view showing the configuration of a second modification of the first embodiment; and

FIG. 52 is a circuit block diagram showing an example of an electronic system.

### DETAILED DESCRIPTION

The present embodiment will be described below in accordance with the accompanying drawings.

### First Embodiment

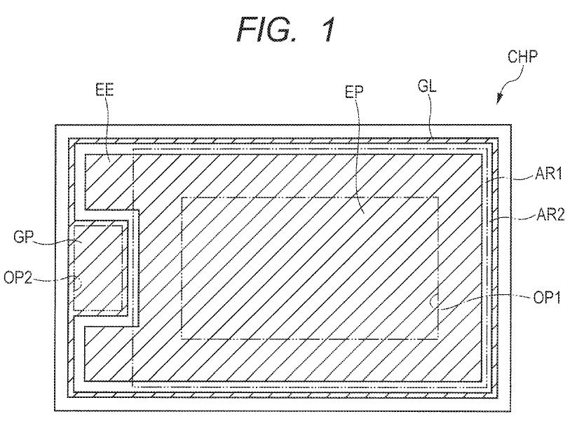

Referring to FIGS. 1 to 6, the configuration of a semiconductor device according to the present embodiment will be first described below. In the following explanation, “in plan view” means a viewpoint in a direction orthogonal to a first major surface of a semiconductor substrate SB.

As shown in FIG. 1, a semiconductor chip CHP serving as a semiconductor device of the present embodiment mainly includes the semiconductor substrate and an IGBT and a diode that are formed on the semiconductor substrate. The semiconductor substrate has the first major surface and a second major surface opposite from the first major surface.

The first major surface of the semiconductor substrate has a cell formation region AR1 and a gate lead region AR2 surrounding the outer periphery of the cell formation region AR1. The IGBT and the diode are formed in the cell formation region AR1 of the semiconductor substrate.

In a most part of the cell formation region AR1, an emitter electrode EE (second electrode) is arranged on the first major surface of the semiconductor substrate.

In the gate lead region AR2, a gate wire GL is arranged. The gate wire GL is electrically coupled to the gate electrode of the IGBT formed on the semiconductor substrate in the cell formation region AR1.

An insulating layer (not shown) is formed on the emitter electrode EE and the gate wire GL. The insulating layer has openings OP1 and OP2. The opening OP1 is arranged in the cell formation region AR1. The opening OP2 is arranged in the gate lead region AR2.

The surface of the emitter electrode EE is partially exposed from the opening OP1 of the insulating layer. The surface of the emitter electrode EE exposed from the opening OP1 includes an emitter pad EP. The gate wire GL is partially exposed from the opening OP2. The surface of the gate wire GL exposed from the opening OP2 includes a gate pad GP.

The semiconductor device of the present embodiment is not limited to a semiconductor chip. The semiconductor device may be a semiconductor wafer or a semiconductor package including a resin-molded semiconductor chip. Alternatively, the semiconductor device of the present embodiment may be a semiconductor module including a semiconductor chip and a semiconductor package.

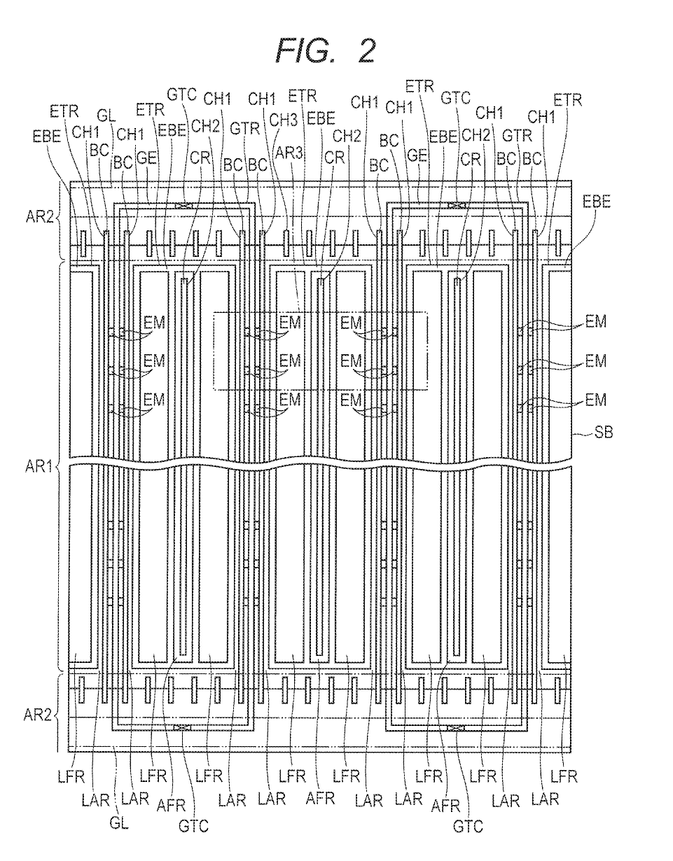

As shown in FIG. 2, the semiconductor substrate SB has emitter grooves ETR and gate grooves GTR on the first major surface. The emitter groove ETR surrounds an anode formation region ARF in plan view. Furthermore, the emitter groove ETR surrounds linear floating regions LFR in plan view.

The anode formation region AFR is interposed between the two linear floating regions LFR in plan view. The emitter groove ETR surrounding the two linear floating regions LFR and the emitter groove ETR surrounding the single anode formation region AFR are coupled to each other.

An emitter groove electrode EBE is embedded in the emitter groove ETR. The emitter groove electrode EBE in the emitter groove ETR is electrically coupled to the emitter electrode EE (FIG. 1) formed on the emitter groove electrode EBE.

The gate groove GTR is located in a region interposed between two linear active regions LAR in plan view. The gate groove GTR in plan view extends from the inside of the gate lead region AR2 on one side of the cell formation region AR1 through the cell formation region AR1 into the gate lead region AR2 on the other side of the cell formation region AR1. The gate groove GTR is shaped like a frame surrounding the outer edge of the emitter groove ETR in plan view.

A gate electrode GE is embedded in the gate groove GTR. The gate electrode GE is electrically coupled to the gate wire GL, which is formed on the gate electrode GE, via a contact GTC in the gate lead region AR2.

An insulating layer (not shown) is formed on the first major surface of the semiconductor substrate SB. The insulating layer has contact holes CH1, CH2, and CH3. The contact hole CH1 reaches n-type emitter regions EM and an anode region (first anode region) in the linear active region LAR, which is interposed between the gate groove GTR and the emitter groove ETR, from the top surface of the insulating layer. The contact hole CH1 in plan view extends from the inside of the gate lead region AR2 on one side of the cell formation region AR1 through the cell formation region AR1 into the gate lead region AR2 on the other side of the cell formation region AR1.

The contact hole CH2 reaches an anode region (second anode region) in the anode formation region AFR from the top surface of the insulating layer. For example, the contact hole CH2 alone is arranged in the anode formation region AFR.

The contact holes CH3 reach a body region in the linear floating region LFR from the top surface of the insulating layer. The contact holes CH3 are arranged in the gate lead region AR2 in plan view.

The emitter electrode EE (second electrode in FIG. 1) is formed on the insulating layer. The emitter electrode EE is electrically coupled to the anode region in the anode formation region AFR, the emitter region and the anode region in the linear active region LAR, and the body region in the linear floating region LFR via the contact holes CH1, CH2, and CH3. The emitter electrode EE is also electrically coupled to the emitter groove electrode EBE. Thus, the n-type emitter regions EM are electrically coupled to the emitter groove electrode EBE via the emitter electrode EE.

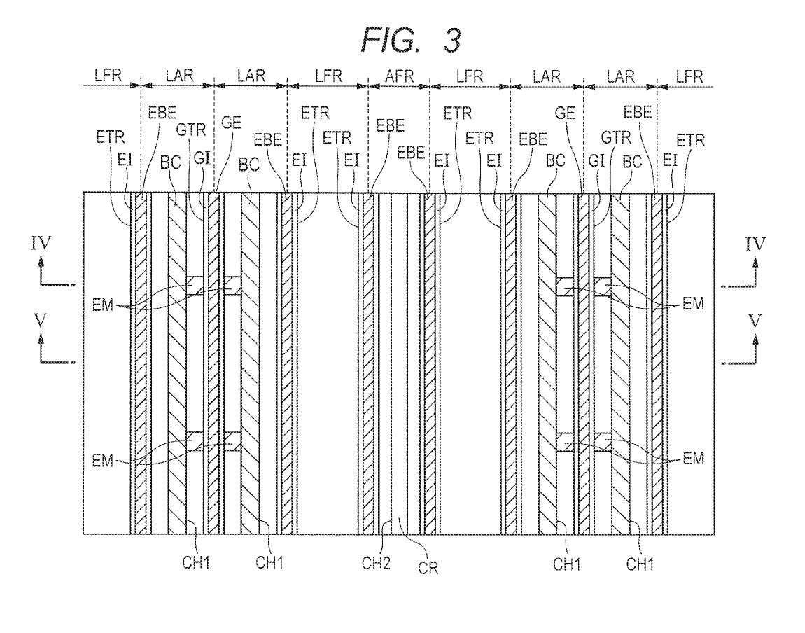

As shown in FIG. 3, the pair of linear floating regions LFR is arranged with the anode formation region AFR interposed between the linear floating regions LFR. The linear floating region LFR is interposed between the anode formation region AFR and the linear active region LAR. The two linear active regions LAR are arranged side-by-side. The two linear active regions LAR arranged side-by-side are interposed between the pair of linear floating regions LFR.

The emitter groove ETR is arranged between (on the border between) the anode formation region AFR and the linear floating region LFR. The emitter groove ETR is arranged between (on the border between) the linear floating region LFR and the linear active region LAR. The gate groove GTR is arranged between (on the border between) the two linear active regions LAR.

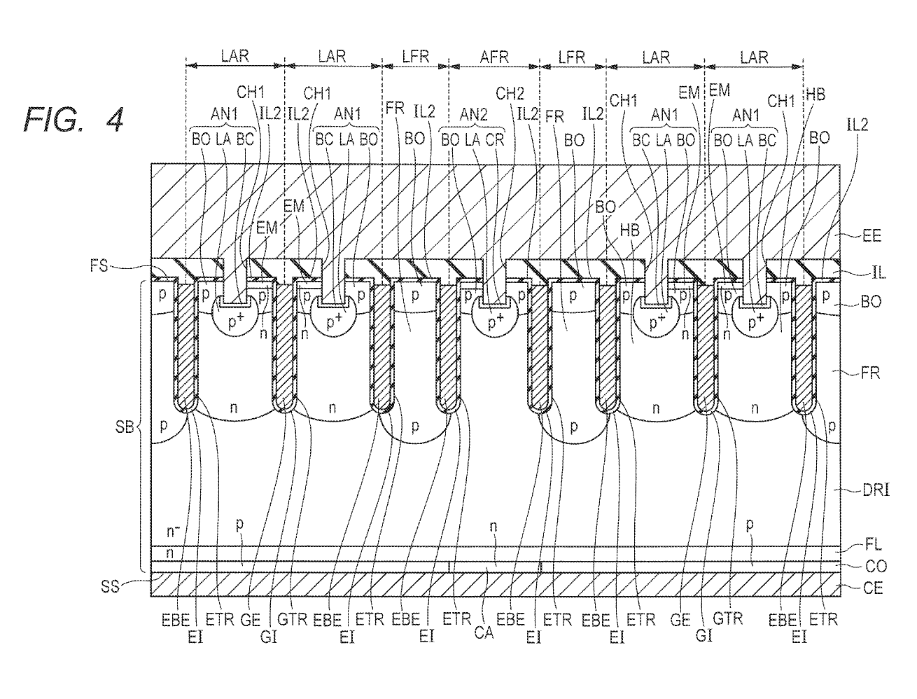

As shown in FIG. 4, the semiconductor substrate SB has a first major surface FS and a second major surface SS opposite from the first major surface FS. IGBTs, first diodes, and second diodes are formed on the semiconductor substrate SB.

The IGBT mainly includes a p-type (first conductivity type) collector region CO, an n-type (second conductivity type) field stop region FL, an n⁻drift region DRI, an n-type hole barrier region HB, a p-type body region BO, the n-type emitter region EM, and the gate electrode GE.

The p-type collector region CO is arranged on the second major surface SS of the semiconductor substrate SB. The n-type field stop region FL is arranged between the p-type collector region CO and the first major surface FS and includes a pn junction with the p-type collector region CO.

The n-drift region DRI is arranged between the n-type field stop region FL and the first major surface FS and is coupled to the n-type field stop region FL. The n⁻drift region DRI has a lower n-type impurity concentration than the n-type field stop region FL. The p-type collector region CO is arranged between the n⁻drift region DRI and the second major surface SS.

The n-type hole barrier region HB is arranged on the n⁻drift region DRI and near the first major surface FS and is coupled to the n⁻drift region DRI. The n-type hole barrier region HB has a higher n-type impurity concentration than the n⁻drift region DRI. The n-type hole barrier region HB is arranged between the n⁻drift region DRI and the p-type body region BO.

The p-type body region BO is arranged on the n-type hole barrier region HB and near the first major surface FS. The p-type body region BO includes a pn junction with the n-type hole barrier region HB. The n⁻drift region DRI is arranged between the p-type body region BO and the p-type collector region CO. The p-type collector region CO is arranged between the p-type body region BO and the second major surface SS. The n-type emitter region EM is arranged on the p-type body region BO and near the first major surface FS. The n-type emitter region EM includes a pn junction with the p-type body region BO.

The n-type emitter region EM is arranged on the first major surface FS of the semiconductor substrate SB and includes the pn junction with the p-type body region BO. Also in a region where the n-type emitter region EM is not formed in the linear active region LAR, the p-type body region BO is arranged on the first major surface FS of the semiconductor substrate SB.

The n-type hole barrier region HB, the p-type body region BO, and the n-type emitter region EM are arranged in the linear active region LAR, that is, in a region interposed between the gate groove GTR and the emitter groove ETR.

The gate groove GTR penetrates the n-type emitter region EM and the p-type body region BO from the first major surface FS of the semiconductor substrate SB and reaches at least the n-type hole barrier region HB. The gate groove GTR may also penetrate the n-type hole barrier region HB and reach the n⁻drift region DRI.

A gate insulating layer GI is arranged along the wall surface of the gate groove GTR. The gate electrode GE is embedded in the gate groove GTR. The gate electrode GE is opposed to the p-type body region BO with the gate insulating layer GI interposed between the gate electrode GE and the p-type body region BO.

The emitter groove ETR penetrates the p-type body region BO and the n-type hole barrier region HB from the first major surface FS of the semiconductor substrate SB and reaches the n⁻drift region DRI.

An emitter insulating layer EI is arranged along the wall surface of the emitter groove ETR. The emitter groove electrode EBE is embedded in the emitter groove ETR.

The first diode mainly includes an n-type cathode region CA, the n-type field stop region FL, the n⁻drift region DRI, the n-type hole barrier region HB, the p-type body region BO, a p⁺ latch-up prevention region LA, and a p⁺ body contact region BC.

The n-type cathode region CA is arranged on the second major surface SS of the semiconductor substrate SB. The n-type cathode region CA is arranged beside the p-type collector region CO and includes a pn junction with the p-type collector region CO.

The n-type field stop region FL is arranged on the n-type cathode region CA and near the first major surface FS and is coupled to the n-type cathode region CA.

The n-type field stop region FL, the n⁻drift region DRI, the n-type hole barrier region HB, and the p-type body region BO of the first diode each include an impurity region shared by the n-type field stop region FL, the n⁻drift region DRI, the n-type hole barrier region HB, and the p-type body region BO of the IGBT.

The p⁺ latch-up prevention region LA of the first diode is located on the border between the n-type hole barrier region HB and the p-type body region BO. Thus, the p⁺ latch-up prevention region LA includes a pn junction with the n-type hole barrier region HB and is joined to the p-type body region BO.

The p⁺ body contact region BC is arranged at a coupling point between the emitter electrode EE and the p⁺ latch-up prevention region LA. Thus, the emitter electrode EE is electrically coupled to the p⁺ latch-up prevention region LA via the p⁺ body contact region BC.

The p⁺ body contact region BC has a higher p-type impurity concentration than the p-type body region BO. The p-type body region BO, the p⁺ latch-up prevention region LA, and the p⁺ body contact region BC of the first diode include an anode region AN1 (first anode region) of the first diode. In other words, the anode region AN1 has the same impurity region as the p-type body region BO in the linear active region LAR.

The second diode mainly includes the n-type cathode region CA, the n-type field stop region FL, the n⁻drift region DRI, the p-type body region BO, a p⁺ body contact region CR, and the p⁺ latch-up prevention region LA.

The n-type cathode region CA, the n-type field stop region FL, and the n⁻drift region DRI of the second diode each include an impurity region shared by the n-type cathode region CA, the n-type field stop region FL, and the n⁻drift region DRI of the first diode. The n-type cathode region CA acts as a cathode for each of the first diode and the second diode.

The p-type body region BO of the second diode is arranged between the n⁻drift region DRI and the first major surface FS. The p-type body region BO includes a pn junction with the n⁻drift region DRI. The p⁺ latch-up prevention region LA of the second diode is located on the border between the n⁻drift region DRI and the p-type body region BO. Thus, the p⁺ latch-up prevention region LA includes a pn junction with the n⁻drift region DRI and is joined to the p-type body region BO.

The p⁺ body contact region CR is arranged at a coupling point between the emitter electrode EE and the p⁻type body region BO. Thus, the emitter electrode EE is electrically coupled to the p-type body region BO via the p⁺ body contact region CR.

The p⁺ body contact region CR has a higher p-type impurity concentration than the p-type body region BO. The p-type body region BO, the p⁺ body contact region CR, and the p⁺ latch-up prevention region LA of the second diode include an anode region AN2 (second anode region) of the second diode.

The anode region AN2 (the p-type body region BO, the p⁺ body contact region CR, and the p⁺ latch-up prevention region LA) of the second diode is arranged in the anode formation region AFR and in a region surrounded by the emitter groove ETR. Thus, the anode region AN2 is separated from the p-type body region BO of the linear active region LAR by the emitter groove ETR. The anode region AN2 includes a pn junction with the n⁻drift region DRI. In the anode formation region AFR, the p-type body region BO is arranged on the first major surface FS of the semiconductor substrate SB.

The linear floating region LFR is arranged between the anode formation region AFR and the linear active region LAR. A p-type floating region FR and the p-type body region BO are arranged in a region surrounded by the emitter groove ETR in the linear floating region LFR.

The p-type floating region FR is arranged on the n⁻drift region DRI and near the first major surface FS. The p-type floating region FR includes a pn junction with the n⁻drift region DRI. The p-type body region BO is arranged on the p-type floating region FR and near the first major surface FS and is coupled to the p-type floating region FR. The p-type body region BO is arranged on the first major surface FS of the semiconductor substrate SB in the linear floating region LFR.

The emitter groove ETR between the anode formation region AFR and the linear active region LAR penetrates the p-type body region BO from the first major surface FS of the semiconductor substrate SB and reaches the n⁻drift region DRI. The emitter insulating layer EI is arranged along the wall surface of the emitter groove ETR. The emitter groove electrode EBE is embedded in the emitter groove ETR.

A thin insulating layer IL2 and a thick insulating layer IL are stacked on the first major surface FS of the semiconductor substrate SB. The insulating layers IL and IL2 have the contact holes CH1 and CH2.

In the linear active region LAR, the contact hole CH1 penetrates the insulating layers IL and IL2 and reaches the p⁺ body contact region BC through the n-type emitter region EM and the p-type body region BO.

In the anode formation region AFR, the contact hole CH2 penetrates the insulating layers IL and IL2 and extends in the p-type body region BO so as to reach the p⁺ body contact region BC.

The emitter electrode EE is arranged on the insulating layer IL. The emitter electrode EE is electrically coupled to the n-type emitter regions EM and the anode regions AN1 via the contact holes CH1. The emitter electrode EE is in contact with the anode region AN2 of the second diode through the contact hole CH2. Thus, the emitter electrode EE is electrically coupled to the anode region AN2 of the second diode via the contact hole CH2.

A collector electrode CE (first electrode) is arranged on the second major surface SS of the semiconductor substrate SB. The collector electrode CE is coupled to the p-type collector region CO and the n-type cathode region CA. Thus, the collector electrode CE is electrically coupled to the p-type collector region CO and the n-type cathode region CA.

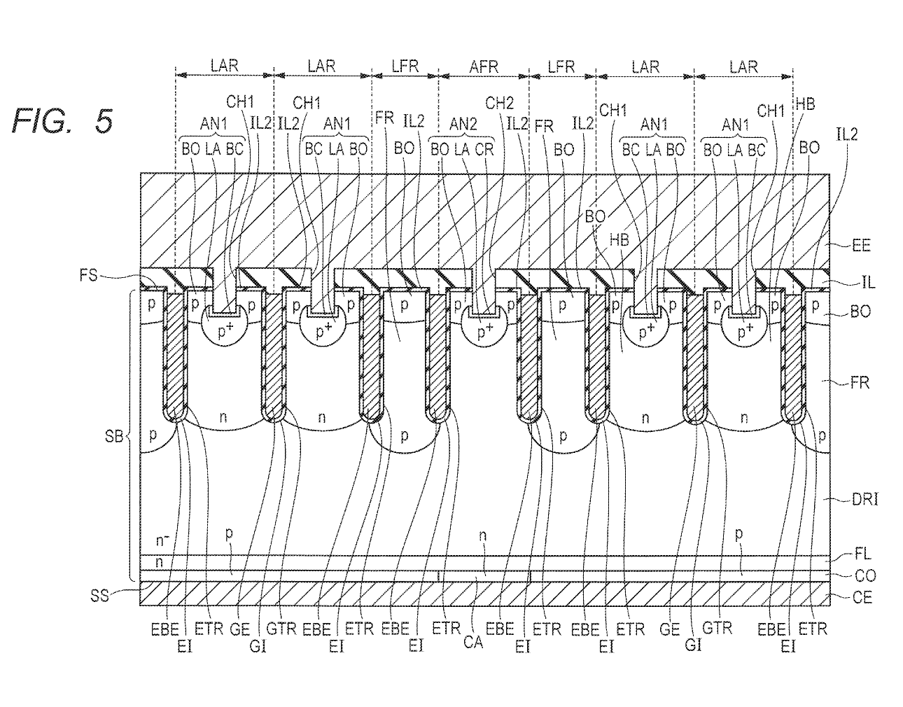

As shown in FIG. 5, in a cross section of a region where the n-type emitter region EM is not arranged in the linear active region LAR, only the p-type body region BO is arranged on the first major surface in the linear active region LAR.

Other configurations in FIG. 5 are substantially identical to those of FIG. 4. Thus, the same constituent elements as those of FIG. 4 are indicated by the same symbols and the explanation thereof will not be repeated.

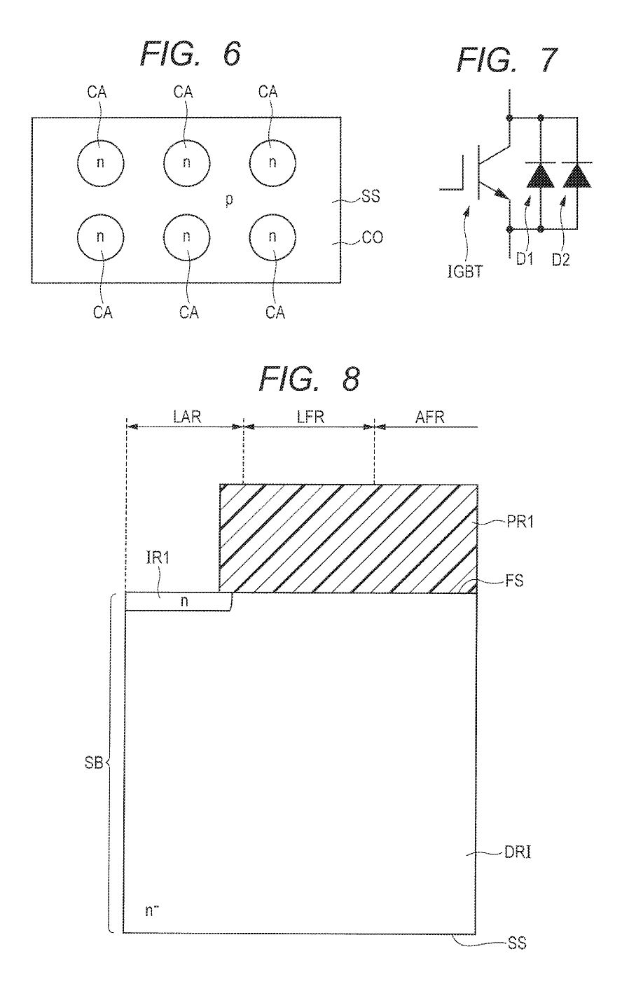

As shown in FIG. 6, on the second major surface SS of the semiconductor substrate SB, the n-type cathode regions CA are separated from one another in the p-type collector region CO. The n-type cathode regions CA may be arranged in rows on the second major surface SS.

The IGBT, the first diode, and the second diode of the present embodiment include a circuit shown in FIG. 7. As shown in FIG. 7, the IGBT, a first diode D1, and a second diode D2 of the present embodiment are coupled in parallel. The anode of the first diode D1 and the anode of the second diode D2 are electrically coupled to the emitter of the IGBT. The cathode of the first diode D1 and the cathode of the second diode D2 are electrically coupled to the collector of the IGBT.

Referring to FIGS. 8 to 28, a method of manufacturing the semiconductor device according to the present embodiment will be described below.

As shown in FIG. 8, the semiconductor substrate SB made of, for example, single crystal silicon is formed by a floating zone method. The semiconductor substrate SB is then oxidized to form a silicon oxide film (not shown) on the surface of the semiconductor substrate SB. The silicon oxide film is etched and removed according to an ordinary photolithographic technique and an ordinary etching technique.

After that, a photoresist pattern PR1 is formed on the first major surface FS of the semiconductor substrate SB according to the ordinary photolithographic technique. The photoresist pattern PR1 covers the linear floating region LFR and the anode formation region AFR with an opening in the linear active region LAR.

An n-type impurity is ion-implanted to the first major surface FS of the semiconductor substrate SB with the photoresist pattern PR1 serving as a mask. For example, the impurity is ion-implanted with implantation energy of 80 keV and a dose of 7×10¹²/cm². This forms an n-type impurity region IR1 on the first major surface FS of the linear active region LAR. After that, the photoresist pattern PR1 is removed by, for example, ashing.

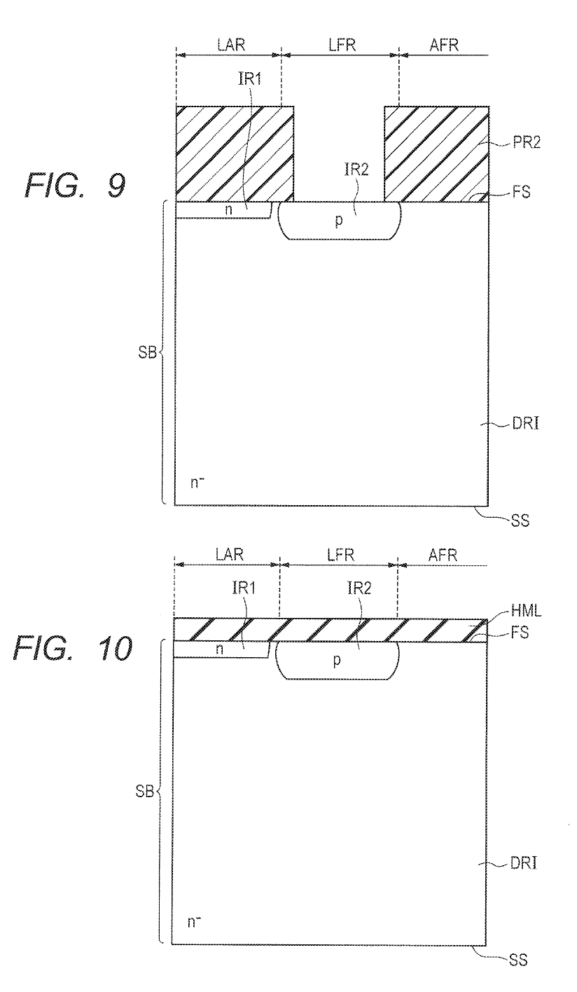

As shown in FIG. 9, a photoresist pattern PR2 is formed on the first major surface FS of the semiconductor substrate SB according to the ordinary photolithographic technique. The photoresist pattern PR2 covers the linear active region LAR and the anode formation region AFR with an opening in the linear floating region LFR.

A p-type impurity is ion-implanted to the first major surface FS of the semiconductor substrate SB with the photoresist pattern PR2 serving as a mask. For example, the impurity is ion-implanted with implantation energy of 75 keV and a dose of 4×10¹³/cm². This forms a p-type impurity region IR2 on the first major surface FS of the linear floating region LFR. After that, the photoresist pattern PR2 is removed by, for example, ashing.

As shown in FIG. 10, an insulating layer HML including a silicon oxide film is formed on the first major surface FS of the semiconductor substrate SB by, for example, chemical vapor deposition (CVD).

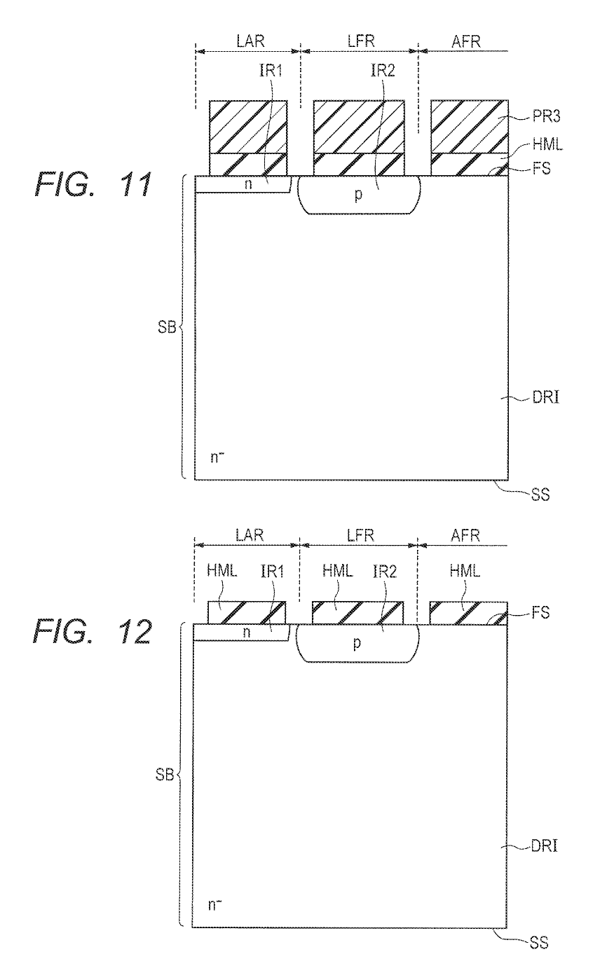

As shown in FIG. 11, a photoresist pattern PR3 is formed on the insulating layer HML according to the ordinary photolithographic technique. The photoresist pattern PR3 is formed with an opening on the border between the linear active region LAR and the linear floating region LFR, an opening on the border between the linear floating region LFR and the anode formation region AFR, and an opening on the border between the linear active regions LAR.

The insulating layer HML is etched with the photoresist pattern PR3 serving as a mask. The insulating layer HML is patterned by the etching. After that, the photoresist pattern PR3 is removed by, for example, ashing.

As shown in FIG. 12, the insulating layer HML is etched so as to form a hard mask layer HML having a desired pattern from the insulating layer. The hard mask layer HML is formed with an opening on the border between the linear active region LAR and the linear floating region LFR, an opening on the border between the linear floating region LFR and the anode formation region AFR, and an opening on the border between the linear active regions LAR.

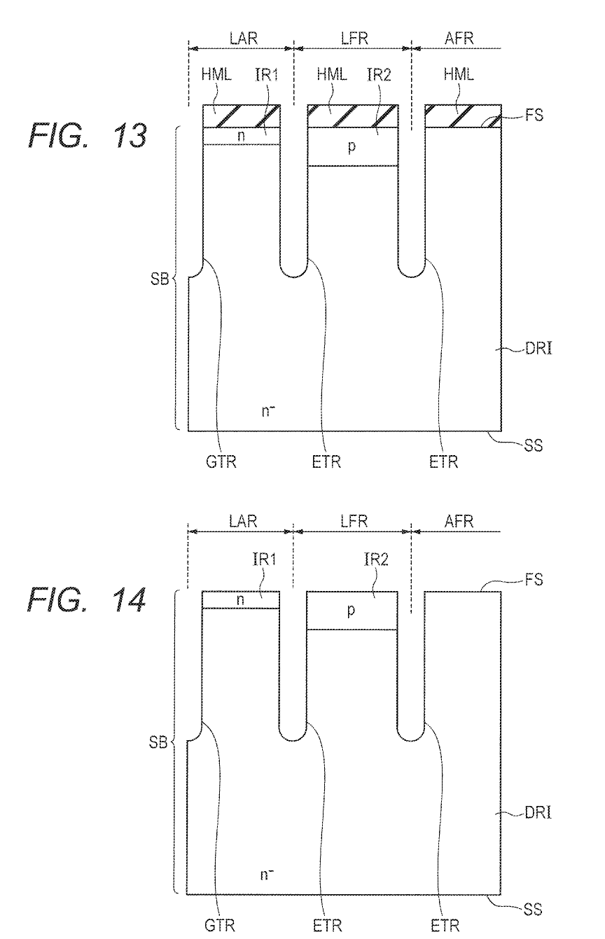

As shown in FIG. 13, the first major surface FS of the semiconductor substrate SB is etched with the hard mask layer HML serving as a mask. Thus, the gate grooves GTR and the emitter grooves ETR are formed on the first major surface FS of the semiconductor substrate SB. For example, the gate grooves GTR and the emitter grooves ETR are 2.5 to 4.0 μm in depth.

The gate groove GTR in this cross section is formed on the border between the linear active regions LAR. The emitter grooves ETR in this cross section are formed on the border between the linear active region LAR and the linear floating region LFR and the border between the linear floating region LFR and the anode formation region AFR. After that, the hard mask layer HML is removed by, for example, etching.

As shown in FIG. 14, the hard mask layer HML is removed so as to expose the first major surface FS of the semiconductor substrate SB.

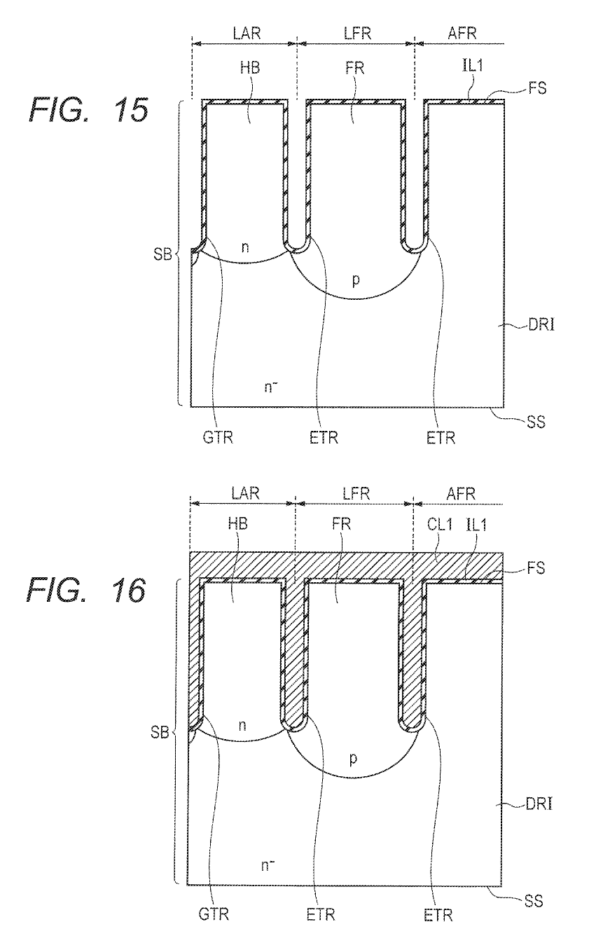

As shown in FIG. 15, the first major surface FS of the semiconductor substrate SB is subjected to sacrificial oxidation. After that, heat treatment is performed to disperse the n-type impurity region IR1 and the p-type impurity region IR2. The heat treatment disperses the n-type impurity region IR1 so as to form the n-type hole barrier region HB in the linear active region LAR. Moreover, the heat treatment disperses the p-type impurity region IR2 so as to form the p-type floating region FR in the linear floating region LFR.

After that, gate oxidation is performed on the first major surface FS of the semiconductor substrate SB. The gate oxidation forms the insulating layer IL1 including a silicon oxide film on the first major surface FS and the wall surfaces of the gate grooves GTR and the emitter grooves ETR.

As shown in FIG. 16, a conductive layer CL1 is formed on the first major surface FS so as to fill the gate grooves GTR and the emitter grooves ETR. The conductive layer CL1 is made of, for example, polycrystalline silicon doped with phosphorus with a thickness of 600 nm. The conductive layer CL1 is then etched back.

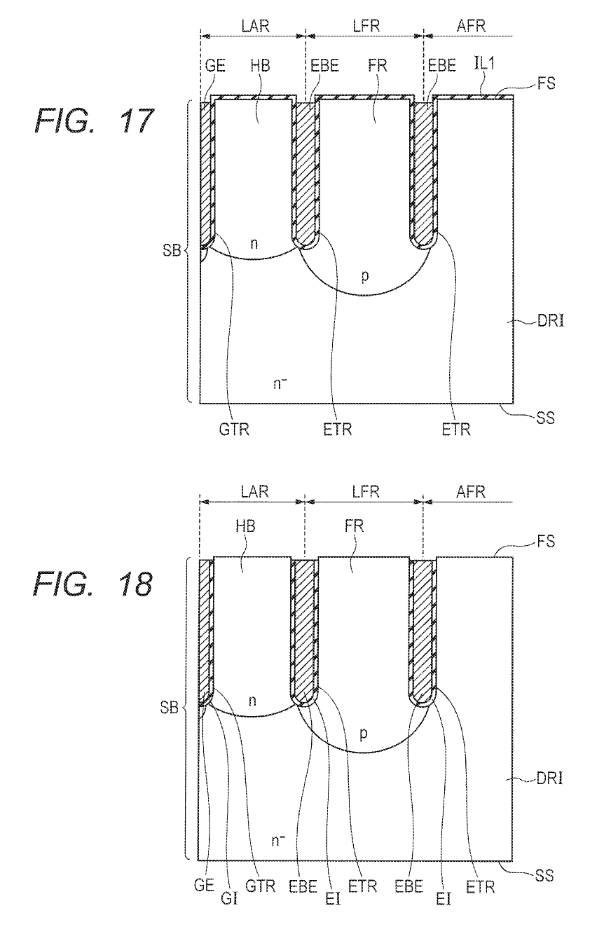

As shown in FIG. 17, the conductive layer CL1 is etched back so as to remain only in the gate grooves GTR and the emitter grooves ETR. The remaining conductive layer CL1 forms the gate electrode GE in the gate groove GTR and forms the emitter groove electrode EBE in the emitter groove ETR. After that, the insulating layer IL1 is etched back.

As shown in FIG. 18, the insulating layer IL1 on the first major surface FS is etched back and removed so as to remain in the gate grooves GTR and the emitter grooves ETR. The insulating layer IL1 remaining in the gate groove GTR serves as the gate insulating layer GI. The insulating layer IL1 remaining in the emitter groove ETR serves as the emitter insulating layer EI.

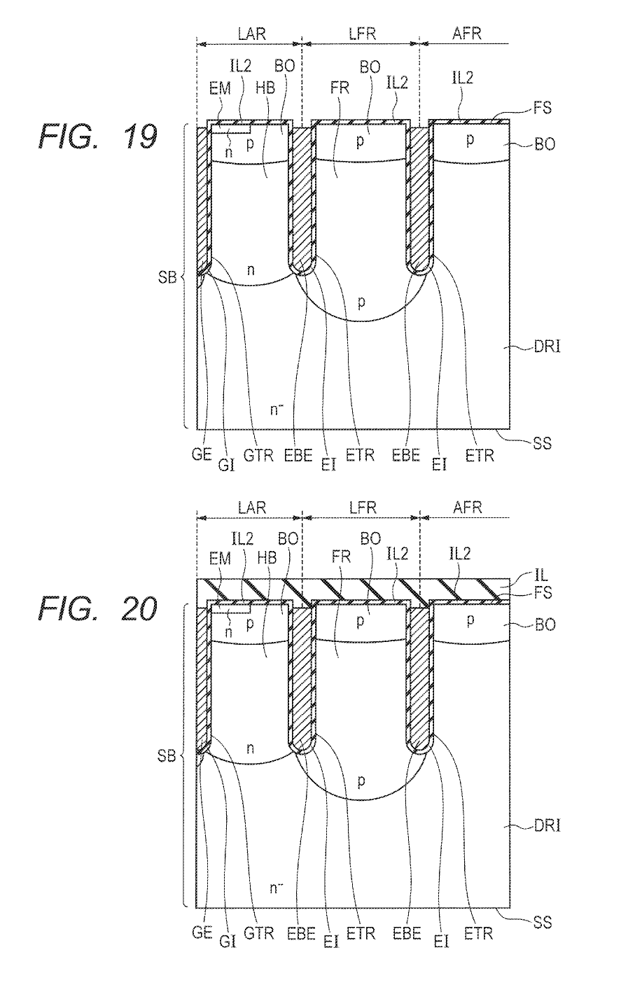

As shown in FIG. 19, the insulating layer IL2 including a silicon oxide film is formed on the first major surface FS by CVD or thermal oxidation. After that, a p-type impurity is ion-implanted to the first major surface FS of the semiconductor substrate SB.

For example, the impurity is ion-implanted with implantation energy of 75 keV and a dose of 0.9 to 1.5×10¹²/cm². Through the ion implantation, the p-type impurity is implanted over the first major surface FS in the cell formation region AR1 (FIGS. 1 and 2). Thus, in each of the linear active region LAR, the linear floating region LFR, and the anode formation region AFR, the p-type body region BO is formed on the first major surface FS of the semiconductor substrate SB.

After that, a photoresist pattern (not shown) is formed according to the ordinary photolithographic technique. An n-type impurity is ion-implanted to the linear active region LAR with the photoresist pattern serving as a mask.

For example, the impurity is ion-implanted with implantation energy of 80 keV and a dose of 5×10′¹/cm². The ion implantation forms the n-type emitter region EM on the first major surface FS in the linear active region LAR. The photoresist pattern is then removed by, for example, ashing.

As shown in FIG. 20, the insulating layer IL is formed on the first major surface FS by, for example, CVD. The insulating layer IL is made of, for example, phosphorus silicon glass (PSG), boron phosphorus silicon glass (BPSG), and non-doped silicate glass (NSG).

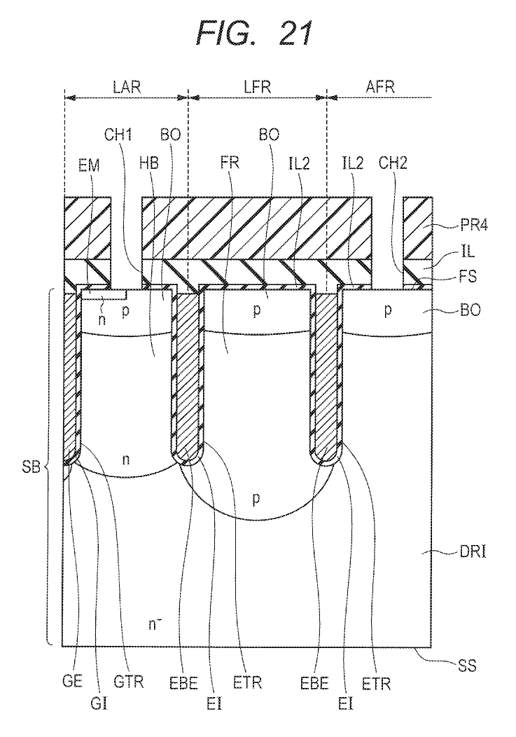

As shown in FIG. 21, a photoresist pattern PR4 is formed on the insulating layer IL according to the ordinary photolithographic technique. The insulating layers IL and IL2 are etched with the photoresist pattern PR4 serving as a mask. This forms the contact holes CH1 and CH2 on the insulating layers IL and IL2. The contact holes CH1 and CH2 are formed so as to reach the first major surface FS.

The contact hole CH1 is formed so as to expose the n-type emitter region EM and the p-type body region BO in the linear active region LAR. The contact hole CH2 is formed so as to expose the p-type body region BO in the anode formation region AFR. After that, the photoresist pattern PR4 is removed by, for example, ashing.

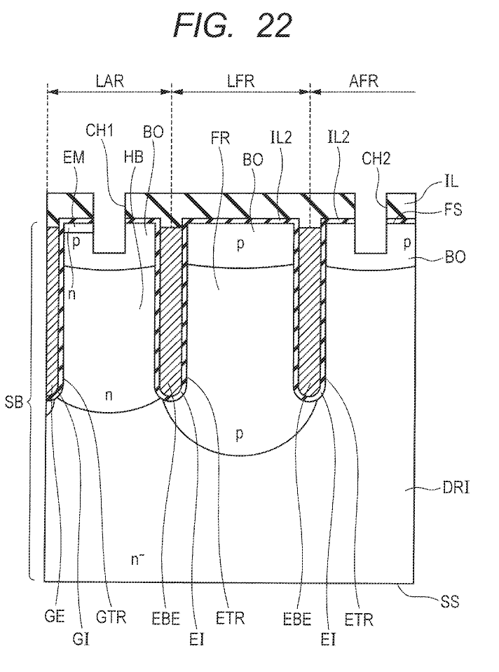

As shown in FIG. 22, the semiconductor substrate SB is etched with the patterned insulating layers IL and IL2 serving as hard masks. Thus, the contact holes CH1 and CH2 are deeply formed into the semiconductor substrate SB. The contact holes CH1 and CH2 are formed with a thickness of, for example, 0.35 μm from the first major surface FS.

Specifically, the contact hole CH1 is formed such that the bottom of the contact hole CH1 is deeper than the n-type emitter region EM in the p-type body region BO. The contact hole CH2 is formed such that the bottom of the contact hole CH2 extends into the p-type body region BO.

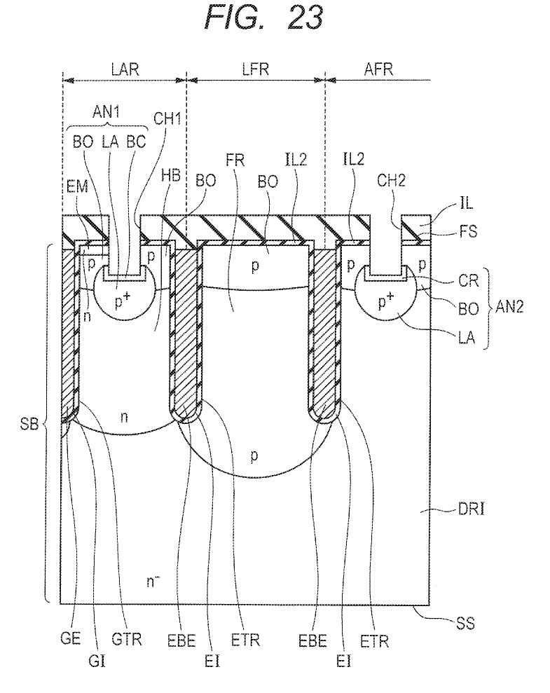

As shown in FIG. 23, a p-type impurity is ion-implanted into the semiconductor substrate SB through the contact holes CH1 and CH2. The impurity is ion-implanted by implanting boron fluoride (BF₂) with, for example, implantation energy of 80 keV and a dose of 5×10¹⁵/cm². The ion implantation forms the p⁺ body contact region BC under the contact hole CH1 and the p⁺ body contact region CR under the contact hole CH2.

Furthermore, a p-type impurity is ion-implanted into the semiconductor substrate SB through the contact holes CH1 and CH2. The impurity is ion-implanted by implanting boron (B) with, for example, implantation energy of 60 keV and a dose of 3×10⁵/cm². The ion implantation forms the p⁺ latch-up prevention regions LA under the contact holes CH1 and CH2.

The p-type body region BO, the p⁺ latch-up prevention region LA, and the p⁺ body contact region BC of the linear active region LAR form the anode region AN1. In other words, the anode region AN1 having the same impurity region as the p-type body region BO is formed.

The p-type body region BO, the p⁺ latch-up prevention region LA, and the p⁺ body contact region CR of the anode formation region AFR form the anode region AN2. The anode region AN2 is formed so as to be separated from the anode region AN1 by the emitter groove ETR.

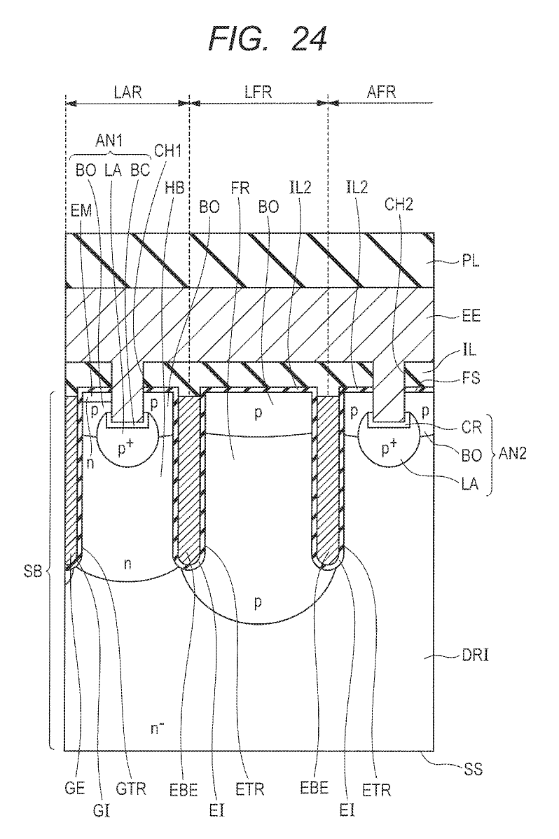

As shown in FIG. 24, the emitter electrode EE is formed on the insulating layer IL. The emitter electrode EE is formed so as to include, for example, a barrier metal layer and an aluminum (Al) layer. The emitter electrode EE is electrically coupled to the n-type emitter region EM of the IGBT and the anode region AN1 (the p-type body region BO, the p⁺ latch-up prevention region LA, and the p⁺ body contact region BC) of the first diode through the contact hole CH1. Moreover, the emitter electrode EE is electrically coupled to the anode region AN2 (the p-type body region BO, the p⁺ latch-up prevention region LA, and the p⁺ body contact region CR) of the second diode through the contact hole CH2.

After that, a protective film PL is formed on the emitter electrode EE. The protective film PL is made of, for example, polyimide.

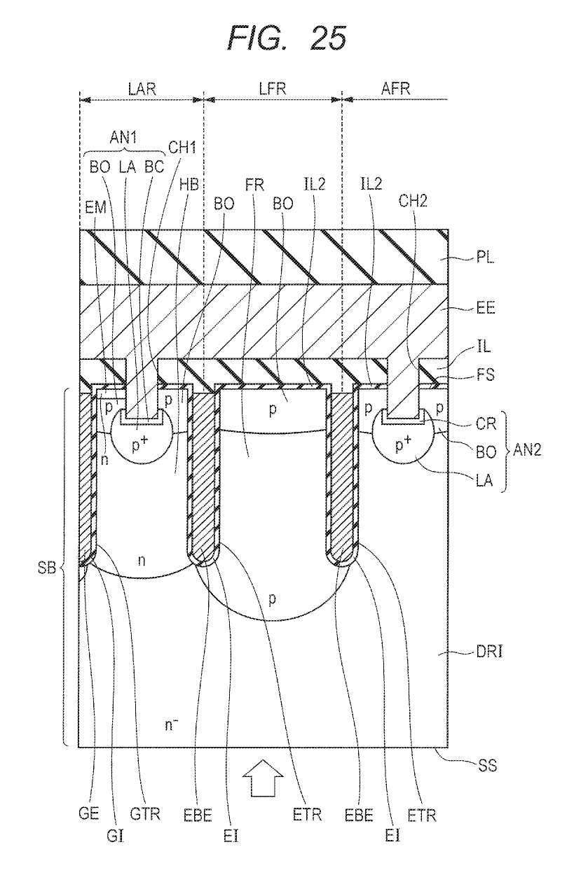

As shown in FIG. 25, the surface of the protective film PL is protected by tape. In this state, the second major surface SS of the semiconductor substrate SB is polished. The thickness of the semiconductor substrate SB is adjusted by polishing the semiconductor substrate SB. The thickness of the semiconductor substrate SB is determined according to a withstand voltage required for the semiconductor device.

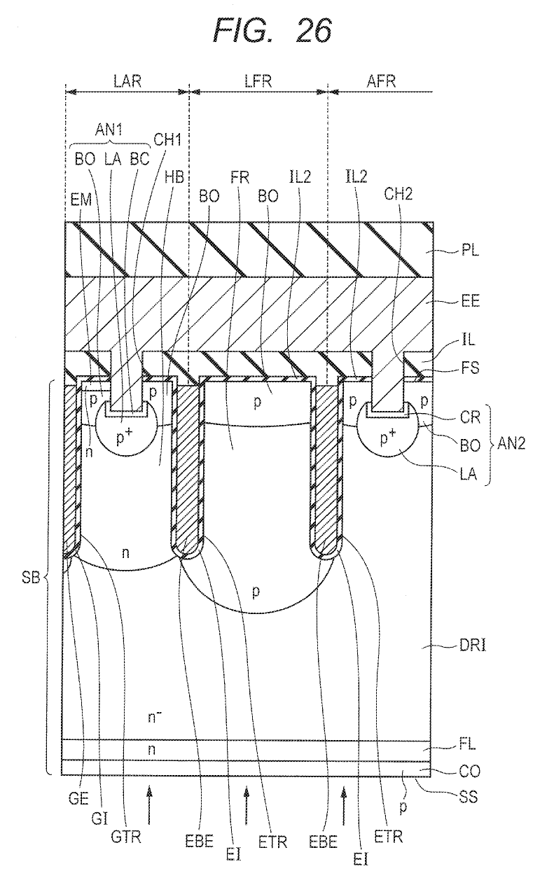

As shown in FIG. 26, the n-type impurity is ion-implanted to the second major surface after the polishing. The impurity is ion-implanted by implanting phosphorus (P) with, for example, implantation energy of 350 keV and a dose of 5×100²/cm². The ion implantation forms the n-type field stop region FL on the second major surface SS.

After the ion implantation, a p-type impurity is ion-implanted to the second major surface. The impurity is ion-implanted by implanting B with, for example, implantation energy of 40 keV and a dose of 7×10¹²/cm² to 4×10¹³/cm². The ion implantation forms the p-type collector region CO on the second major surface SS.

This forms the IGBT including the p-type body region BO, the n-type emitter region EM, and the collector region CO on the semiconductor substrate SB.

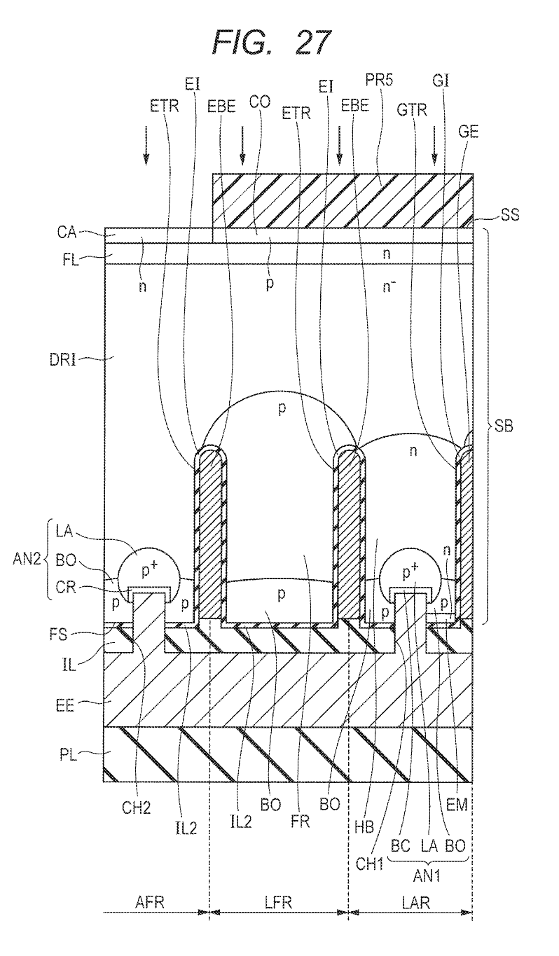

As shown in FIG. 27, a photoresist pattern PR5 is formed on the second major surface SS according to the ordinary photolithographic technique. An n-type impurity is ion-implanted to the second major surface with the photoresist pattern PR5 serving as a mask. The impurity is ion-implanted by implanting P with, for example, implantation energy of 80 keV and a dose of 1×10⁴/cm². After that, laser annealing is performed. Through the ion implantation and so on, the n-type cathode regions CA acting as the cathodes of the first diode and the second diode are formed on the second major surface SS. The photoresist pattern PR5 is then removed by, for example, ashing.

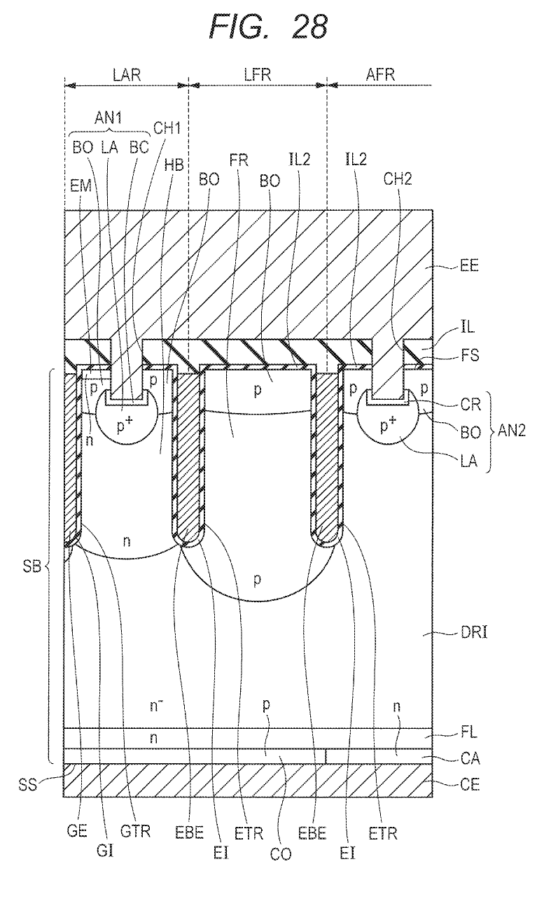

As shown in FIG. 28, the collector electrode CE is formed on the second major surface SS. The collector electrode CE is formed in contact with the n-type cathode regions CA and the p-type collector region CO. Thus, the collector electrode CE is electrically coupled to the n-type cathode region CA and the p-type collector region CO.

The semiconductor device according to the present embodiment is manufactured thus.

The effects of the present embodiment will be described below.

According to the present embodiment, as shown in FIG. 4, the emitter electrode EE is electrically coupled to the anode region AN2 (the p-type body region BO, the p⁺ body contact region CR, and the p⁺ latch-up prevention region LA) in the anode formation region AFR. The anode region AN2 is surrounded by the emitter groove electrode EBE having the same potential as the n-type emitter region EM. Even when the driving signal is inputted to the gate electrode GE of the IGBT so as to turn on the IGBT, a forward voltage Vf of the second diode is not increased.

Specifically, when the IGBT is turned on, a part opposed to the gate electrode GE of the p-type body region BO in the linear active region LAR is inverted to n-type so as to couple the n-type emitter region EM to the n⁻drift region DRI via an n-type layer. This allows the p-type body region BO in the linear active region LAR to have the same potential as the n⁻drift region DRI.

However, the anode region AN2 in the anode formation region AFR is surrounded by the emitter groove electrode EBE having the same potential as the n-type emitter region EM. This electrically isolates the anode region AN2 in the anode formation region AFR from the p-type body region BO in the linear active region LAR. Thus, even when the IGBT is turned on, the anode region AN2 does not have the same potential as the n⁻drift region DRI. This does not increase the forward voltage Vf of the second diode having the anode region AN2, suppressing an increase in the switching loss of the semiconductor device.

The anode region AN2 in the anode formation region AFR also serves as a carrier (hole) ejection path when the IGBT is turned off. Thus, the IGBT is quickly turned off so as to reduce a switching loss when the IGBT is turned off.

Moreover, the anode region AN2 in the anode formation region AFR can be designed with the same dimensions as the linear active region LAR or smaller dimensions than the linear active region LAR. This restricts the ejection of holes from the anode formation region AFR during an on operation of the IGBT. In addition, the effect of increasing hole accumulation in the p-type floating region FR is maintained. Thus, a saturation voltage (V_{CE(sat)}) of the IGBT can be reduced.

A trade-off is made between the saturation voltage (V_{CE(sat)}) and the turn-off power loss of the IGBT. Thus, main characteristics (low switching characteristics or low saturation voltage (V_{CE(sat)}) characteristics) required for each use can be achieved by adjusting the width of the anode region AN2 in the anode formation region AFR.

The p-type floating region FR is surrounded by the emitter groove ETR and is not adjacent to the gate groove GTR. This reduces noise to the gate electrode GE during an operation of the IGBT.

### Improvement Example 1 of the First Embodiment

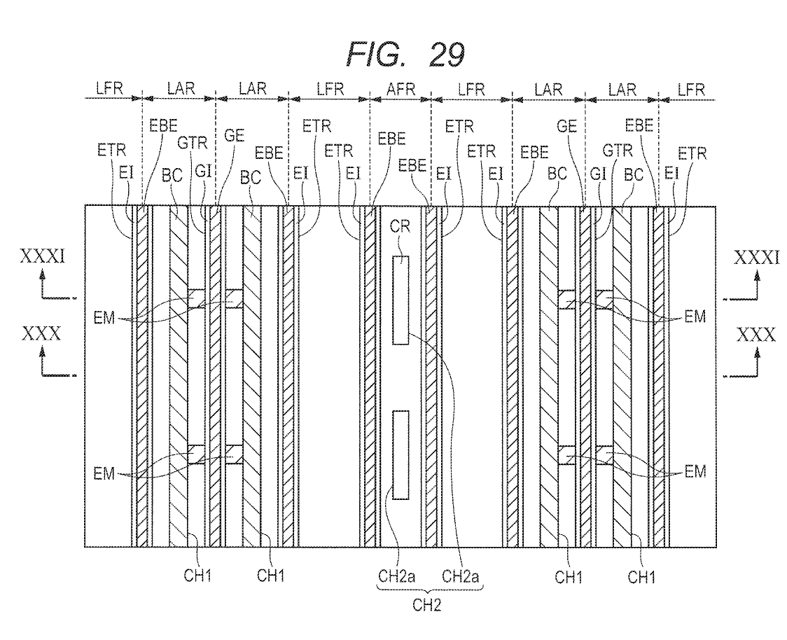

As shown in FIG. 29, the configuration of the present example is different from the configuration of the first embodiment shown in FIGS. 2 to 6 in the shape of the contact hole CH2. In the present embodiment, the contact hole CH2 has a plurality of hole parts CH2a in a region surrounded by the emitter groove ETR in plan view. The hole parts CH2a are separated from each other. The hole parts CH2a are linearly arranged in plan view. The hole parts CH2a are arranged along the longitudinal direction of a region surrounded by the emitter groove ETR in plan view.

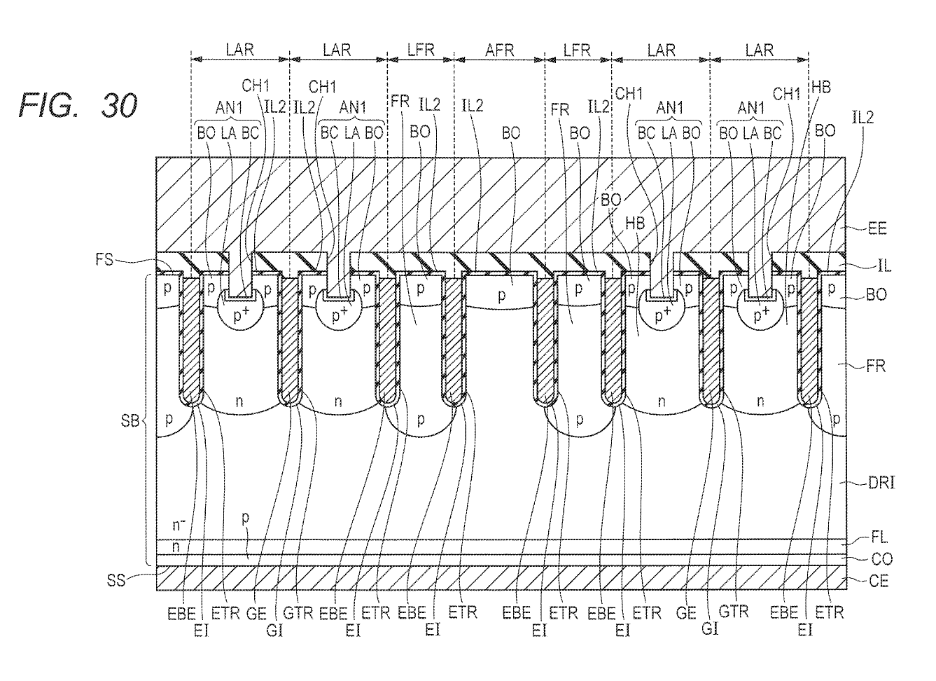

As shown in FIG. 30, in the cross section of a part interposed between the hole parts CH2a of the contact hole CH2, the contact hole CH2 is not formed in the anode formation region AFR of the insulating layer IL. Thus, in the cross section, the insulating layer IL is formed on the first major surface FS of the semiconductor substrate SB in the overall anode formation region AFR.

Other configurations of the present improvement example are substantially identical to those of the first embodiment shown in FIGS. 2 to 6. Thus, the same elements as those of the first embodiment are indicated by the same symbols in the present improvement example and the explanation thereof will not be repeated.

In the present improvement example, the hole parts CH2a including the contact hole CH2 are intermittently arranged in plan view. This increases the resistance of the hole ejection path during an operation of the IGBT, thereby improving an IE effect. Thus, characteristics can be obtained with a lower saturation voltage (V_{CE(sat)}).

### Improvement Example 2 of the First Embodiment

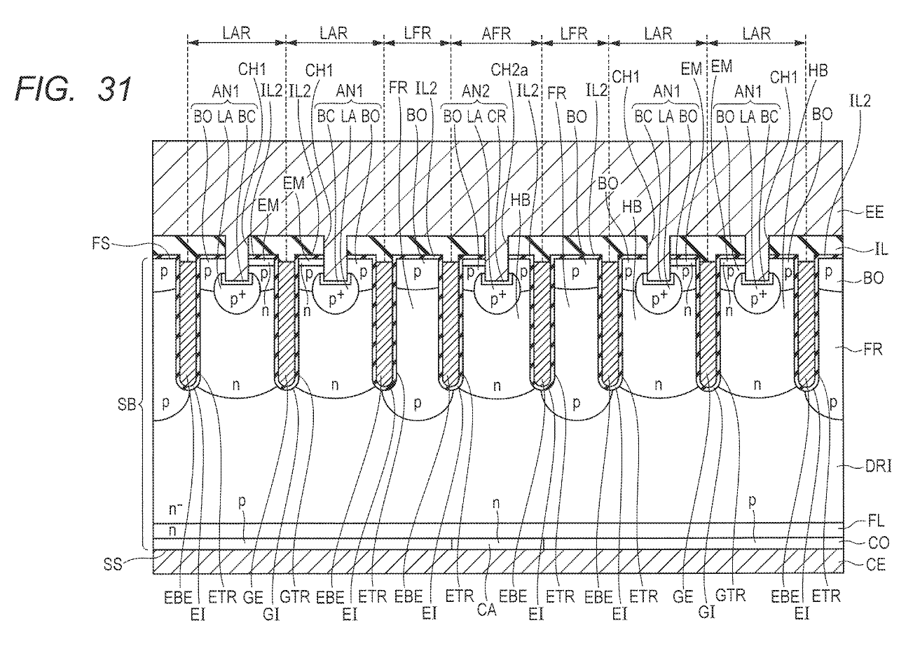

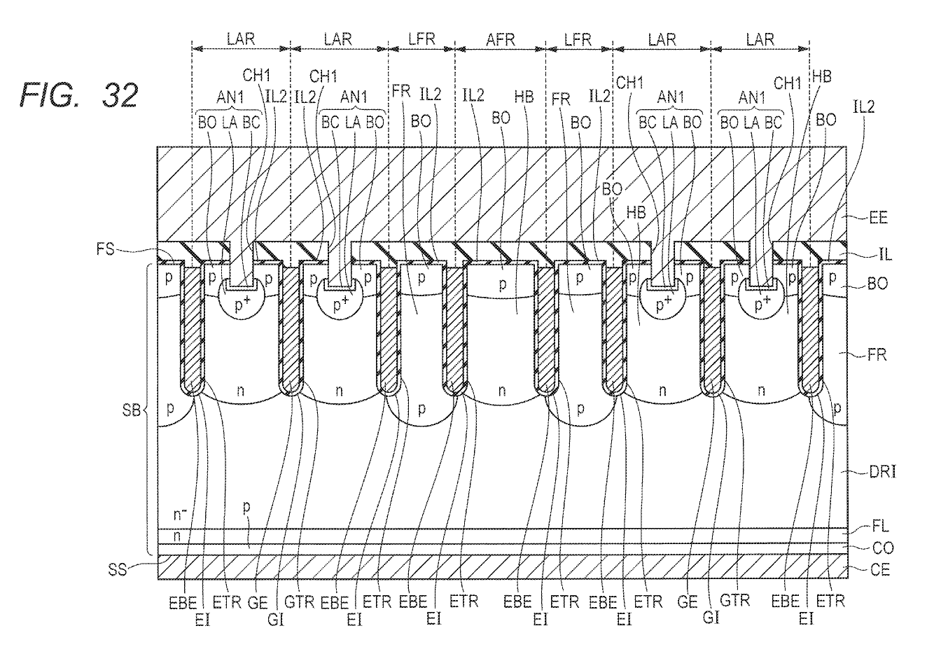

As shown in FIGS. 31 and 32, the configuration of the present improvement example is different from that of improvement example 1 in that the n-type hole barrier region HB is added to the anode formation region AFR.

The n-type hole barrier region HB is located between the p-type body region BO and the second major surface SS in the anode formation region AFR. The n-type hole barrier region HB includes a pn junction with each of the p-type body region BO and the anode region AN2. The n-type hole barrier region HB is interposed between the n⁻drift region DRI and the p-type body region BO. The n-type hole barrier region HB has a higher n-type impurity concentration than the n⁻drift region DRI. The n-type hole barrier region HB is formed in a region surrounded by the emitter groove ETR.

Other configurations of the present improvement example are substantially identical to those of improvement example 1. Thus, the same elements as those of improvement example 1 are indicated by the same symbols and the explanation thereof will not be repeated.

In the present improvement example, the n-type hole barrier region HB is added to the anode formation region AFR. This suppresses hole ejection from the anode formation region AFR during an operation of the IGBT, thereby improving the IE effect. Thus, characteristics can be obtained with a lower saturation voltage (V_{CE(sat)}).

In the present improvement example 2, the n-type hole barrier region HB is added to the configuration of improvement example 1. The same effect can be obtained also by adding the n-type hole barrier region HB to the configuration of the first embodiment shown in FIGS. 2 to 6.

### Second Embodiment

The present embodiment will describe a configuration suitable for use in which a load short-circuit tolerance is not necessary for ultra-low saturation voltage (V_{CE(sat)}) characteristics required for an induction heating cooker, a power factor correction (PFC) circuit, and so on.

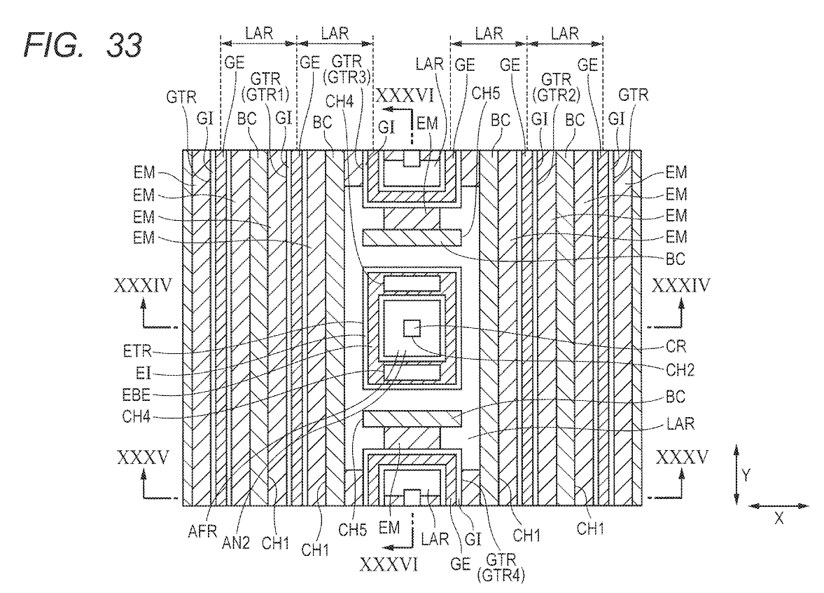

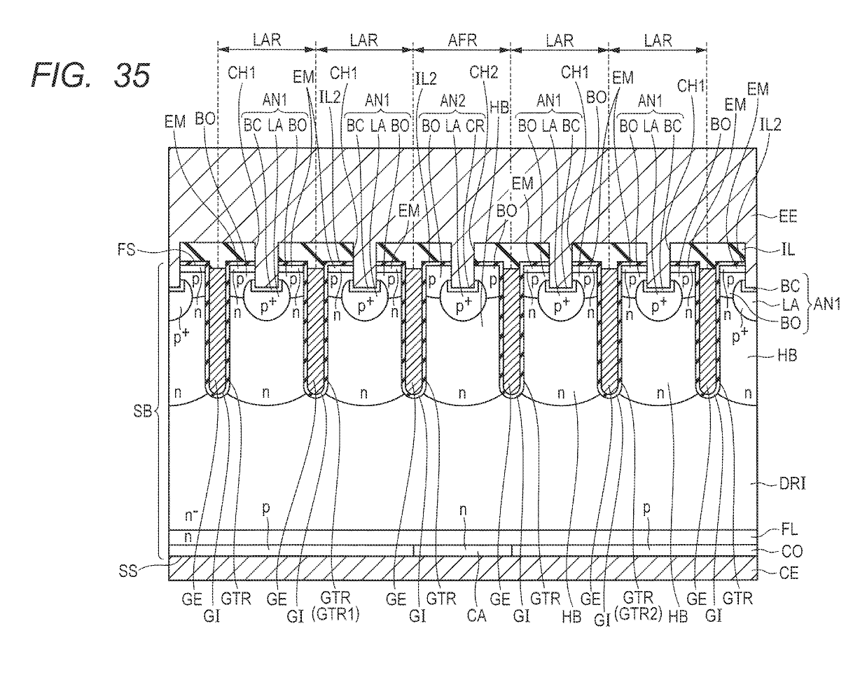

As shown in FIGS. 33 to 36, the configuration of the present embodiment is different from that of the first embodiment shown in FIGS. 2 to 6 in the following points:

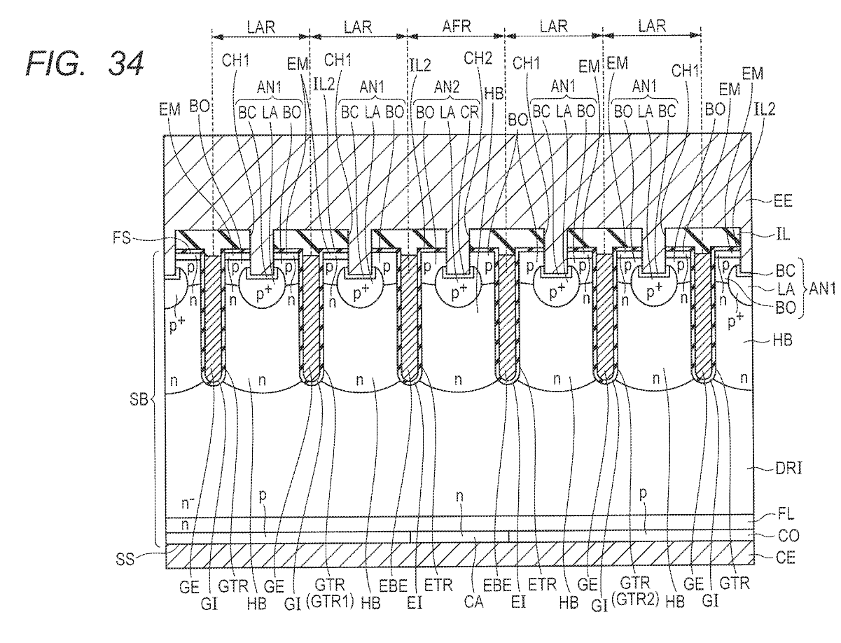

First, in the present embodiment, linear active regions LAR are arranged around an anode formation region AFR in plan view in FIG. 33. Moreover, an n-type emitter region EM in the linear active region LAR is arranged substantially over one side of a gate groove GTR. A linear floating region LFR is omitted. As shown in FIGS. 34 to 36, a p⁺ latch-up prevention region LA and an n-type hole barrier region HB are added to the anode formation region AFR.

As shown in FIG. 33, in the present embodiment, the linear active regions LAR are arranged around the anode formation region AFR in plan view. Specifically, IGBTs and first diodes in the linear active regions LAR are arranged around the anode formation region AFR in plan view. Moreover, the gate grooves GTR are arranged around the anode formation region AFR in plan view.

In this configuration, the longitudinal direction of the gate groove GTR is denoted as Y direction while a crosswise direction orthogonal to the longitudinal direction is denoted as X direction. The gate groove GTR has a first gate groove part GTR1 and a second gate groove part GTR2 with the anode formation region AFR interposed between the first and second gate groove parts GTR1 and GTR2 in X direction in plan view, and a third gate groove part GTR3 and a fourth gate groove part GTR4 with the anode formation region AFR interposed between the third and fourth gate groove parts GTR3 and GTR4 in Y direction in plan view.

Moreover, the n-type emitter region EM is arranged substantially over one side of the gate groove GTR. Specifically, the n-type emitter region EM is arranged over one side of each of the first and second gate grooves GTR1 and GTR2 that are arranged in the X direction of the anode formation region AFR in plan view. The n-type emitter region EM and a p-type body region BO are arranged on one side of each of the third and fourth gate groove parts GTR3 and GTR4 arranged in the Y direction of the anode formation region AFR in plan view.

The p-type body region BO arranged on one side of the gate groove GTR in plan view partially serves as a channel formation region having an emitter potential in the IGBT and also serves as the anode of an FWD (first diode).

As shown in FIGS. 33 to 36, the linear floating region LFR is omitted in the present embodiment. Thus, the linear floating region LFR is not provided between the anode formation region AFR and the linear active region LAR.

The anode formation region AFR is surrounded by an emitter groove ETR in plan view in FIG. 33. Thus, the emitter groove ETR is arranged between the anode formation region AFR and the linear active region LAR.

As shown in FIGS. 34 to 36, the emitter groove ETR surrounding the anode formation region AFR is in contact with the p-type body region BO and the n-type hole barrier region HB of the anode formation region AFR. The emitter groove ETR surrounding the anode formation region AFR is in contact with the p-type body region BO and the n-type hole barrier region HB of the linear active region LAR.

Moreover, the n-type hole barrier region HB and the p⁺ latch-up prevention region LA are added to the anode formation region AFR.

The n-type hole barrier region HB of the anode formation region AFR is arranged between a first major surface FS and an n⁻drift region DRI and is coupled to the n⁻drift region DRI. The n-type hole barrier region HB has a higher n-type impurity concentration than the n⁻drift region DRI. The n-type hole barrier region HB is arranged between a second major surface SS and the p-type body region BO and includes a pn junction with each of the p-type body region BO and an anode region AN2. The n-type hole barrier region HB is formed in a region surrounded by the emitter groove ETR.

The p⁺ latch-up prevention region LA of the anode formation region AFR is arranged on the border between the n-type hole barrier region HB and the p-type body region BO. Thus, the p⁺ latch-up prevention region LA includes a pn junction with the n-type hole barrier region HB and is joined to the p-type body region BO. The p⁺ latch-up prevention region LA, the p-type body region BO, and a p⁺ body contact region CR of the anode formation region AFR include the anode region AN2 of a second diode.

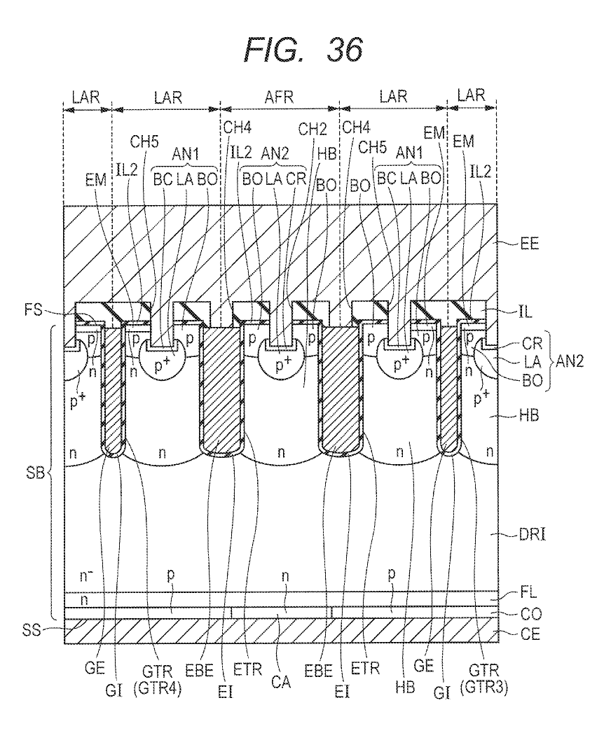

As shown in FIGS. 33 and 36, insulating layers IL and IL2 have contact holes CH4. The contact hole CH4 reaches an emitter groove electrode EBE in the emitter groove ETR. An emitter electrode EE is electrically coupled to emitter groove electrodes EBE via the contact holes CH4.

Moreover, contact holes CH5 are formed on the insulating layers IL and IL2. The contact hole CH5 is arranged between the emitter groove ETR and the gate groove GTR arranged in the Y direction of the emitter groove ETR.

The contact hole CH5 reaches the n-type emitter region EM and an anode region AN1 (first anode region) in the linear active region LAR. The emitter electrode EE is electrically coupled to the emitter groove electrodes EBE via the contact holes CH5.

The contact holes CH1 and CH5 (first holes) reaching the anode region AN1, the contact holes CH2 (second holes) reaching the anode region AN2, and the contact holes CH4 (third holes) reaching the emitter groove electrodes EBE are separated from one another.

Other configurations of the present embodiment are substantially identical to those of the first embodiment shown in FIGS. 2 to 5. Thus, the same elements as those of the first embodiment are indicated by the same symbols in the present embodiment and the explanation thereof will not be repeated.

As shown in FIG. 33, as in the first embodiment, the anode region AN2 (the p-type body region BO, the p⁺ latch-up prevention region LA, and the p⁺ body contact region CR) of the anode formation region AFR in the present embodiment is surrounded by the emitter groove electrode EBE having the same potential as the n-type emitter region EM. Thus, even when a driving signal is inputted to a gate electrode GE of the IGBT to turn on the IGBT, a forward voltage Vf of the second diode is not increased.

The gate grooves GTR (GTR1 to GTR4) are formed around the emitter groove ETR, that is, outside the emitter groove ETR in plan view. Thus, the n-type emitter region EM can be arranged substantially over the first major surface FS so as to minimize a region where the n-type emitter region EM is not formed. This can further suppress saturation voltage (V_{CE(sat)}) characteristics.

### Improvement Example 1 of the Second Embodiment

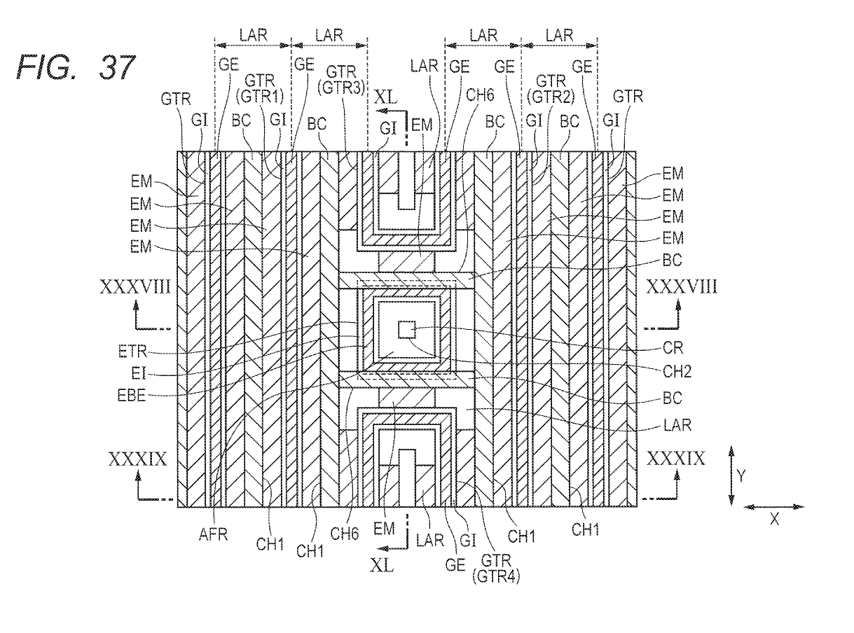

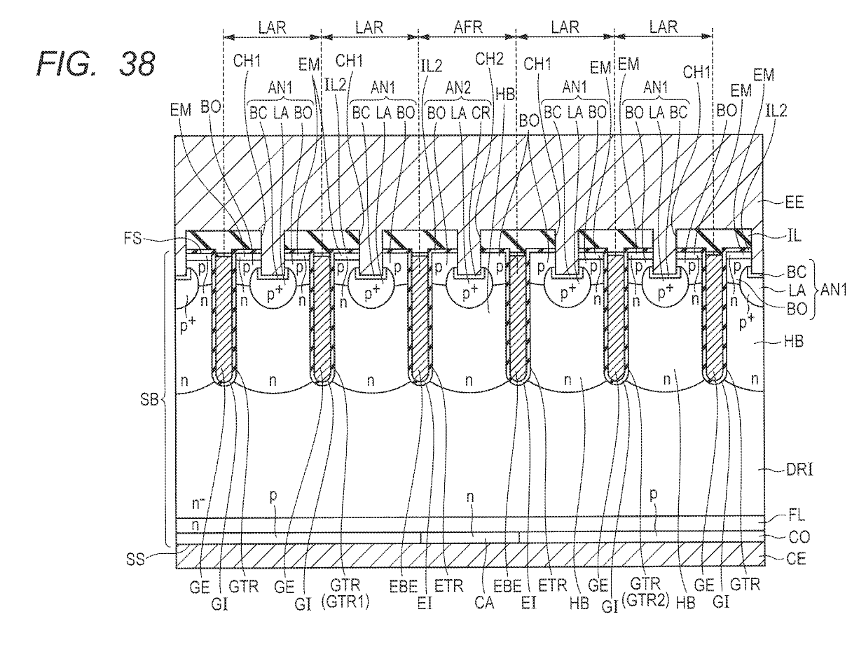

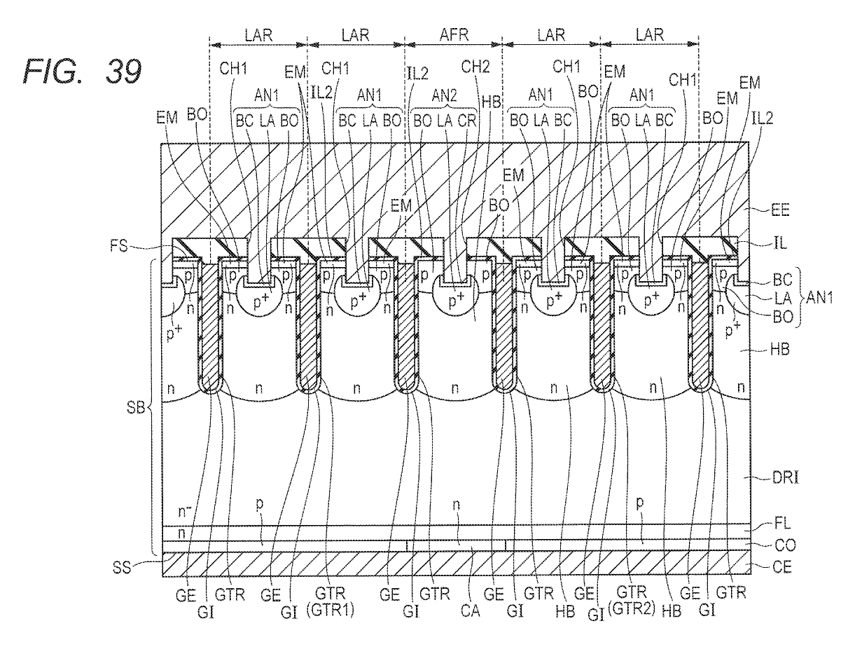

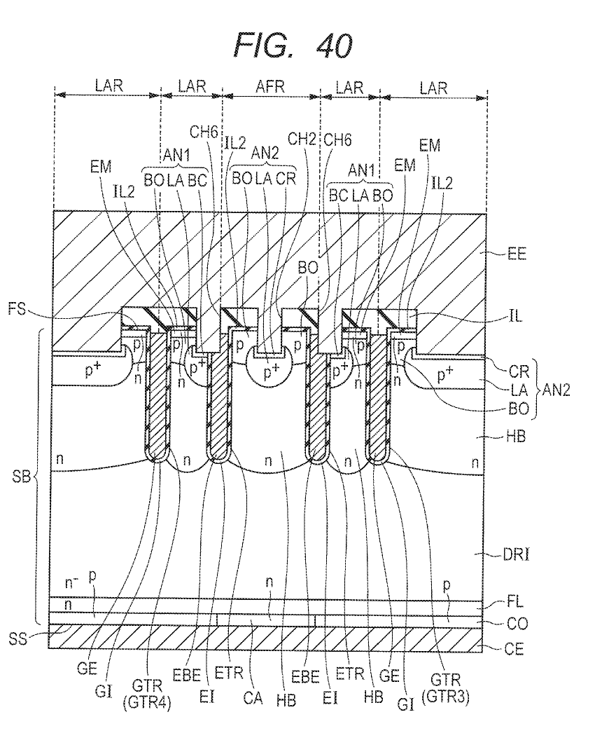

As shown in FIGS. 37 to 40, the configuration of the present improvement example is different from that of the second embodiment in the configuration of a contact hole CH6. As shown in FIG. 40, the contact hole CH6 of the present improvement example reaches the emitter groove electrode EBE, the n-type emitter region EM, and the anode region AN1. As shown in FIG. 37, the contact holes CH6 extend in X direction so as to be coupled to the pair of contact holes CH1 with the emitter groove ETR interposed between the contact holes CH1 in X direction. The contact holes CH6 are separated from the contact hole CH2 reaching the anode region AN2.

Other configurations of the present improvement example are substantially identical to those of the second embodiment. Thus, the same elements as those of the second embodiment are indicated by the same symbols in the present improvement example and the explanation thereof will not be repeated.

In the present improvement example, the contact hole CH6 reaches the emitter groove electrode EBE, the n-type emitter region EM, and the anode region AN1. Thus, in the present improvement example, the contact holes CH4 and the contact holes CH5 do not need to be additionally provided unlike in the second embodiment shown in FIG. 33. This eliminates the need for a space between the contact hole CH4 and the contact hole CH5 unlike in the second embodiment shown in FIG. 33. Thus, the area of the n-type emitter region EM arranged on the first major surface can be extended according to the reduced space, thereby further suppressing the saturation voltage (V_{CE(sat)}) characteristics. Furthermore, a smaller chip size can be obtained while keeping the same characteristics, achieving more inexpensive RC-IGBT products.

### Improvement Example 2 of the Second Embodiment

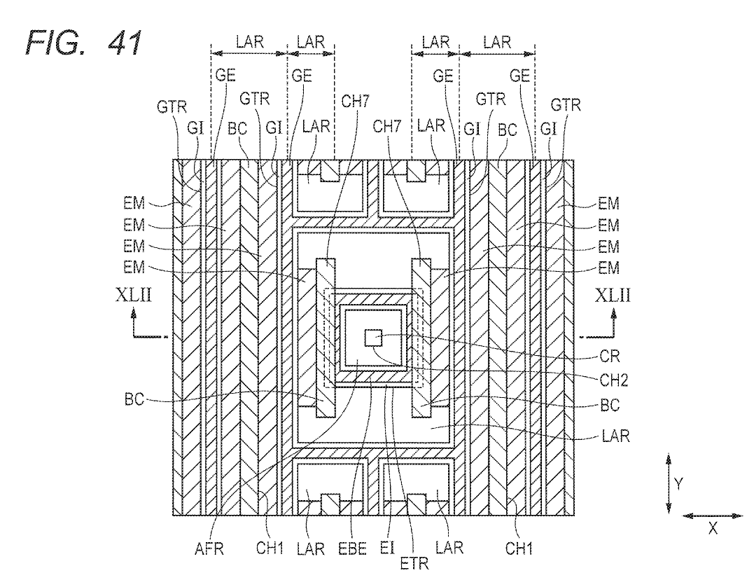

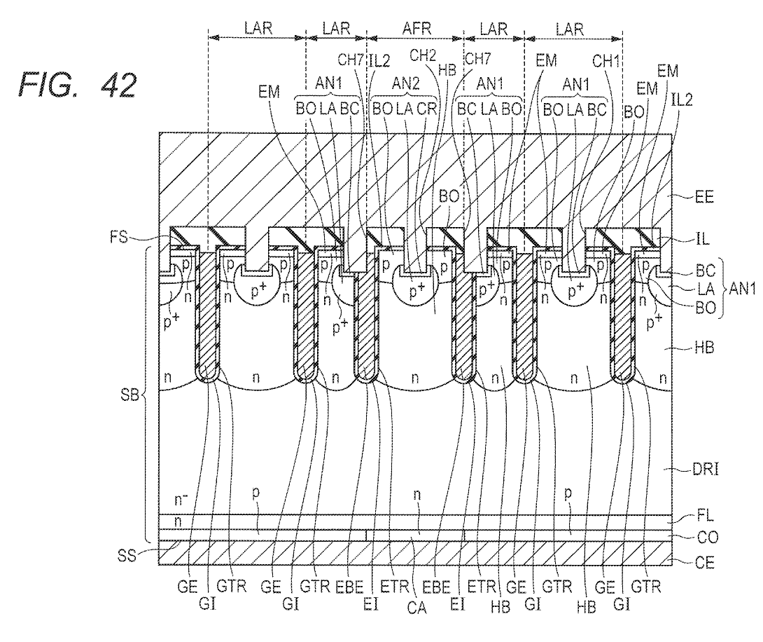

As shown in FIGS. 41 and 42, the configuration of the present improvement example is different from that of improvement example 1 in FIGS. 37 to 40 in the following points:

First, in the present improvement example, the gate groove GTR surrounds the emitter groove ETR around the anode formation region AFR in plan view in FIG. 41. Contact holes CH7 reaching the emitter groove electrode EBE, the n-type emitter region EM, and the anode region AN1 extend in Y direction. The n-type emitter region EM is formed on the first major surface FS between the contact hole CH7 and the gate groove GTR. The contact hole CH7 is separated from the contact hole CH2 reaching the anode region AN2.

Other configurations of the present improvement example are substantially identical to those of improvement example 1 shown in FIGS. 37 to 40. Thus, the same elements as those of improvement example 1 are indicated by the same symbols in the present improvement example and the explanation thereof will not be repeated.

In the present improvement example, as shown in FIG. 42, the contact hole CH7 reaches the emitter groove electrode EBE, the n-type emitter region EM, and the anode region AN1. Thus, in the present improvement example, the contact holes CH4 and the contact holes CH5 do not need to be additionally provided unlike in the second embodiment shown in FIG. 33. This eliminates the need for a space between the contact hole CH4 and the contact hole CH5 unlike in the second embodiment shown in FIG. 33. Thus, the area of the n-type emitter region EM arranged on the first major surface can be extended according to the reduced space, thereby further suppressing the saturation voltage (V_{CE(sat)}) characteristics. Furthermore, a smaller chip size can be obtained while keeping the same characteristics, achieving more inexpensive RC-IGBT products.

### Improvement Example 3 of the Second Embodiment

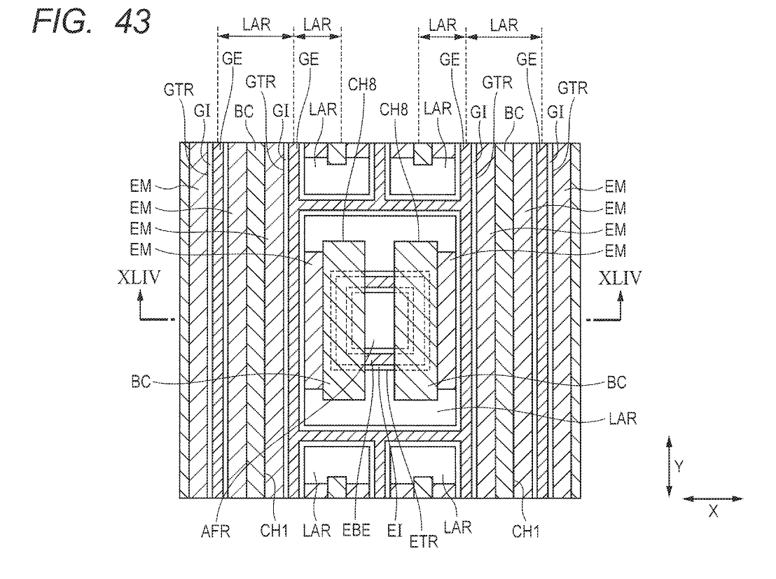

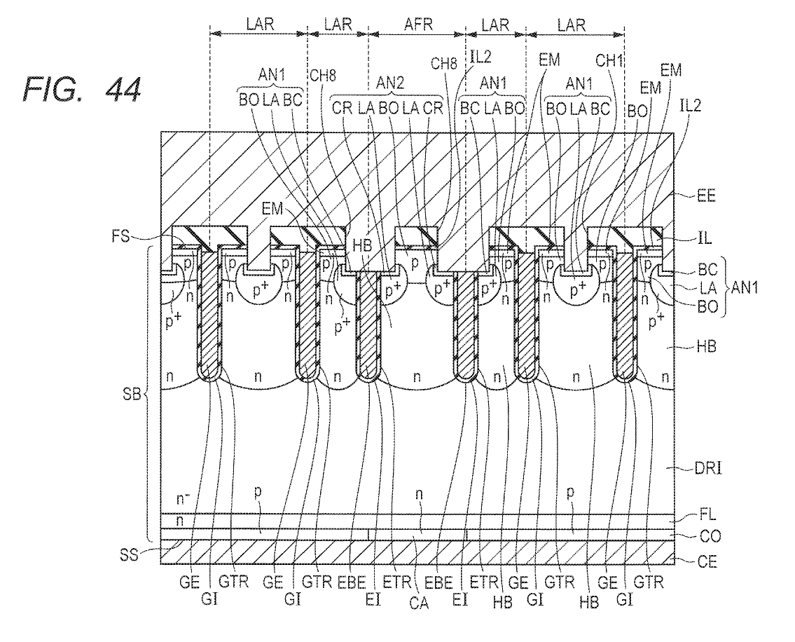

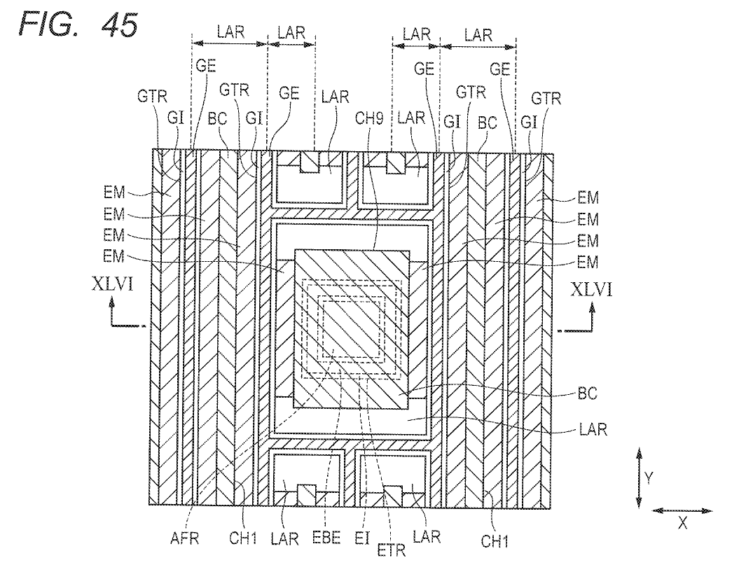

As shown in FIGS. 43 and 44, the configuration of the present improvement example is different from that of improvement example 2 in FIGS. 41 and 42 in the configuration of a contact hole CH8. As shown in FIG. 44, the contact hole CH8 of the present improvement example reaches the anode region AN2 of the anode formation region AFR as well as the emitter groove electrode EBE, the n-type emitter region EM, and the anode region AN1 of the linear active region LAR.

As shown in FIG. 43, the two contact holes CH8 are arranged in X direction. One of the two contact holes CH8 is arranged above a first side of the frame-like emitter groove ETR in plan view. The other of the two contact holes CH8 is arranged above a second side opposed to the first side of the frame-like emitter groove ETR in plan view.

Other configurations of the present improvement example are substantially identical to those of improvement example 2 shown in FIGS. 41 and 42. Thus, the same elements as those of improvement example 2 are indicated by the same symbols in the present improvement example and the explanation thereof will not be repeated.

In the present improvement example, the contact hole CH8 reaches the anode region AN2 of the anode formation region AFR as well as the emitter groove electrode EBE, the n-type emitter region EM, and the anode region AN1 of the linear active region LAR. Thus, in the present improvement example, the contact holes CH7 and the contact holes CH2 do not need to be additionally provided unlike in improvement example 2 shown in FIGS. 41 and 42. This eliminates the need for a space between the contact hole CH7 and the contact hole CH2 unlike in improvement example 2 in FIGS. 41 and 42. Thus, the area of the n-type emitter region EM arranged on the first major surface can be extended according to the reduced space, thereby further suppressing the saturation voltage (V_{CE(sat)}) characteristics. Furthermore, a smaller chip size can be obtained while keeping the same characteristics, achieving more inexpensive RC-IGBT products.

### Improvement Example 4 of the Second Embodiment

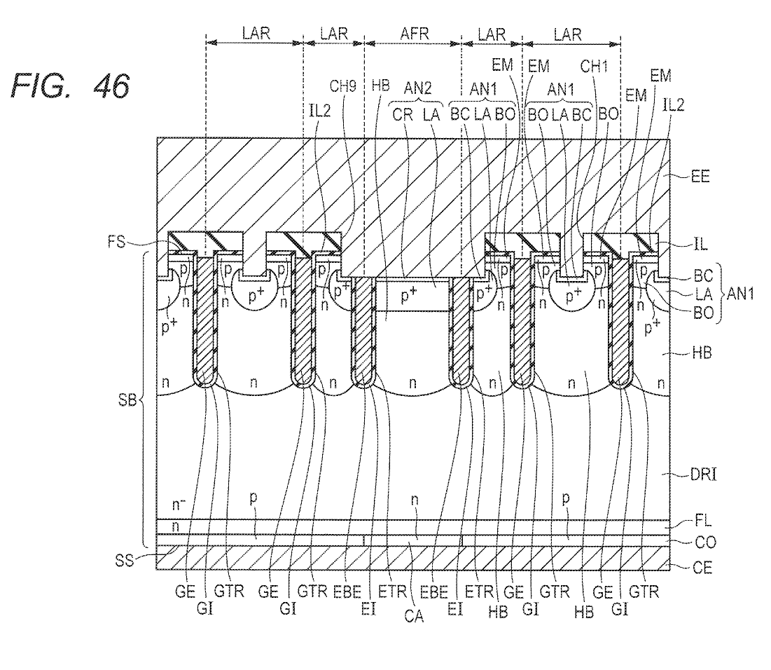

As shown in FIGS. 45 and 46, the configuration of the present improvement example is different from that of improvement example 3 in FIGS. 43 to 44 in the configuration of a contact hole CH9 and the configuration of the anode region AN2. The contact hole CH9 of the present improvement example is laid over the anode region AN2 (the p⁺ latch-up prevention region LA and the p⁺ body contact region CR) of the anode formation region AFR and over the emitter groove ETR surrounding the anode region AN2 in plan view. The contact hole CH9 also overlaps the anode region AN1 surrounding the outer edge of the emitter groove ETR in plan view.

As shown in FIG. 46, the contact hole CH9 reaches the overall anode region AN2 of the anode formation region AFR, the overall emitter groove ETR surrounding the anode region AN2, and the anode region AN1 surrounding the outer edge of the emitter groove ETR.

The anode region AN2 is configured with the p⁺ latch-up prevention region LA and the p⁺ body contact region CR. The p⁺ body contact region CR is formed over the first major surface FS in the anode formation region AFR surrounded by the emitter groove ETR in plan view. The p⁺ latch-up prevention region LA is formed over the p⁺ body contact region CR, between the second major surface SS and the p⁺ body contact region CR.

Other configurations of the present improvement example are substantially identical to those of improvement example 3 shown in FIGS. 43 and 44. Thus, the same elements as those of improvement example 3 are indicated by the same symbols in the present improvement example and the explanation thereof will not be repeated.

In the present improvement example, the contact hole CH9 is not divided into two unlike the contact holes CH8 of improvement example 3 shown in FIGS. 43 and 44. This eliminates the need for a space between the two contact holes CH8 unlike in improvement example 3 shown in FIGS. 43 and 44. Thus, the plane area of the anode region AN2 of the anode formation region AFR can be reduced according to the reduced space. The area of the n-type emitter region EM arranged on the first major surface can be extended according to the reduced plane area of the anode region AN2, thereby further suppressing the saturation voltage (V_{CE(sat)}) characteristics. Furthermore, a smaller chip size can be obtained while keeping the same characteristics, achieving more inexpensive RC-IGBT products.

### Improvement Example 5 of the Second Embodiment

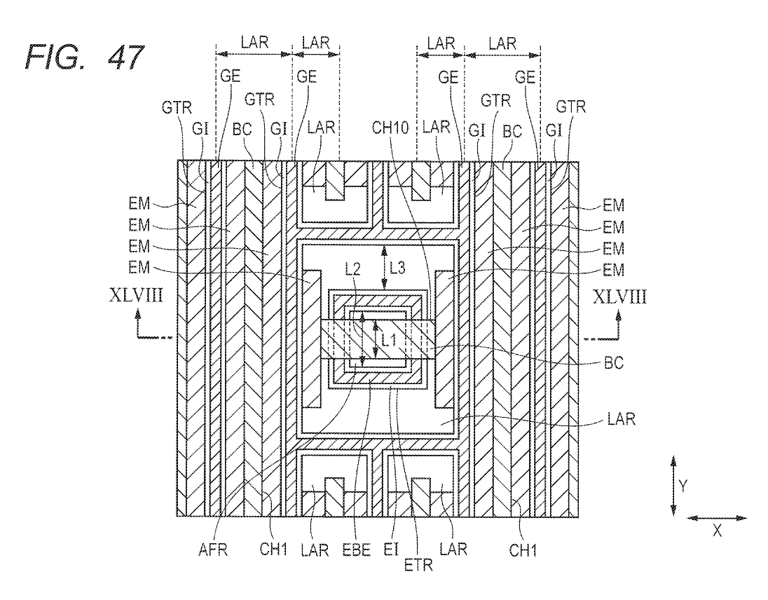

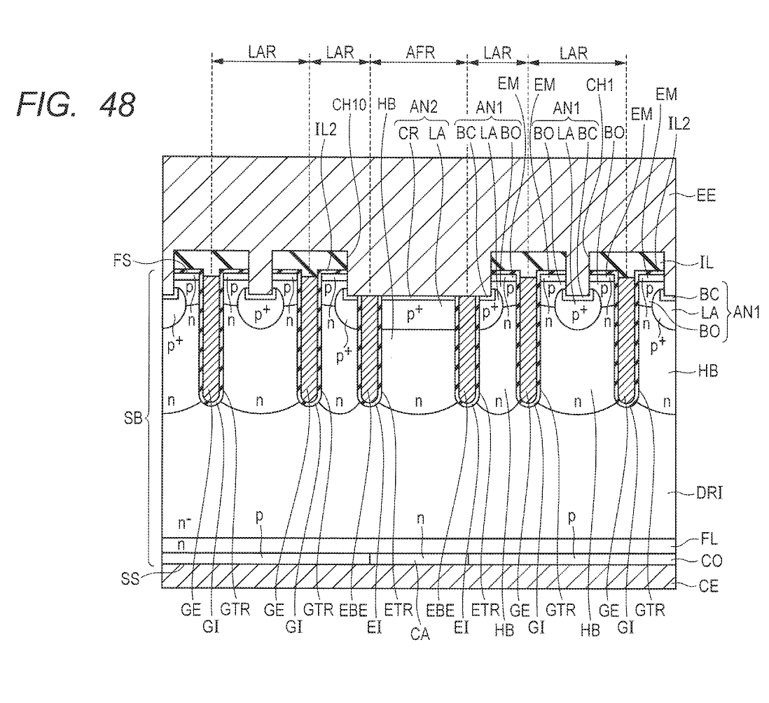

As shown in FIGS. 47 and 48, the configuration of the present improvement example is different from that of improvement example 4 in FIGS. 45 and 46 in the configuration of a contact hole CH10. The contact hole CH10 of the present improvement example is arranged across the anode region AN2 (the p⁺ latch-up prevention region LA and the p⁺ body contact region CR) of the anode formation region AFR, the emitter groove ETR surrounding the anode region AN2, and the anode region AN1 surrounding the outer edge of the emitter groove ETR. A dimension L1 of the contact hole CH10 in Y direction is set smaller than a dimension L2 of the anode region AN2 of the anode formation region AFR in Y direction.

As shown in FIG. 48, the contact hole CH10 reaches a part of the anode region AN2 of the anode formation region AFR, a part of the emitter groove ETR surrounding the anode region AN2, and a part of the anode region AN1 surrounding the outer edge of the emitter groove ETR.

Other configurations of the present improvement example are substantially identical to those of improvement example 4 shown in FIGS. 45 and 46. Thus, the same elements as those of improvement example 4 are indicated by the same symbols in the present improvement example and the explanation thereof will not be repeated.

In present improvement example, the contact hole CH10 has the dimension L1 that is smaller than the dimension L2 of the anode region AN2 in the anode formation region AFR in Y direction. This can reduce a distance L3 between the emitter groove ETR and the gate groove GTR arranged in the Y direction of the emitter groove ETR, unlike in improvement example 4 shown in FIGS. 45 and 46. Thus, the area of the n-type emitter region EM arranged on the first major surface can be extended according to the reduced space between the emitter groove ETR and the gate groove GTR, thereby further suppressing the saturation voltage (V_{CE(sat)}) characteristics. Furthermore, a smaller chip size can be obtained while keeping the same characteristics, achieving more inexpensive RC-IGBT products.

### First Modification

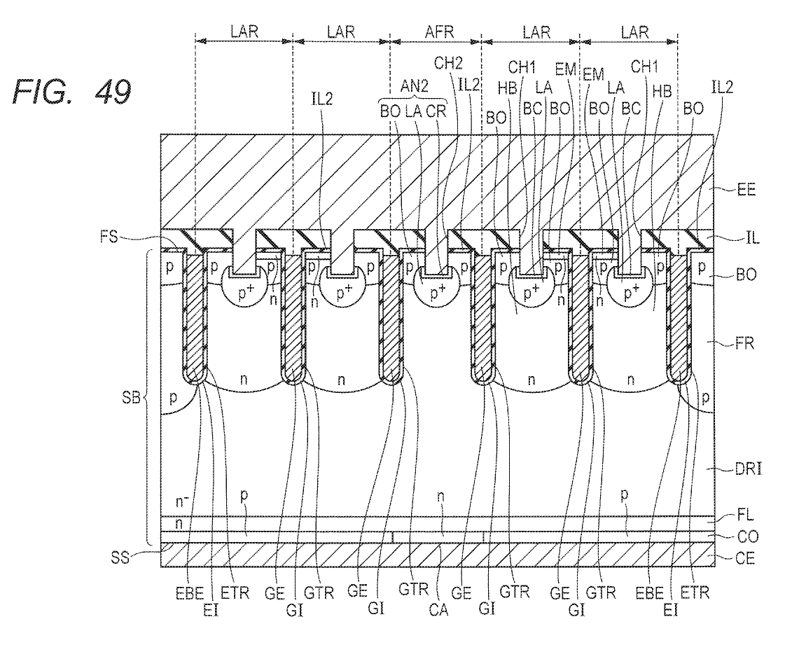

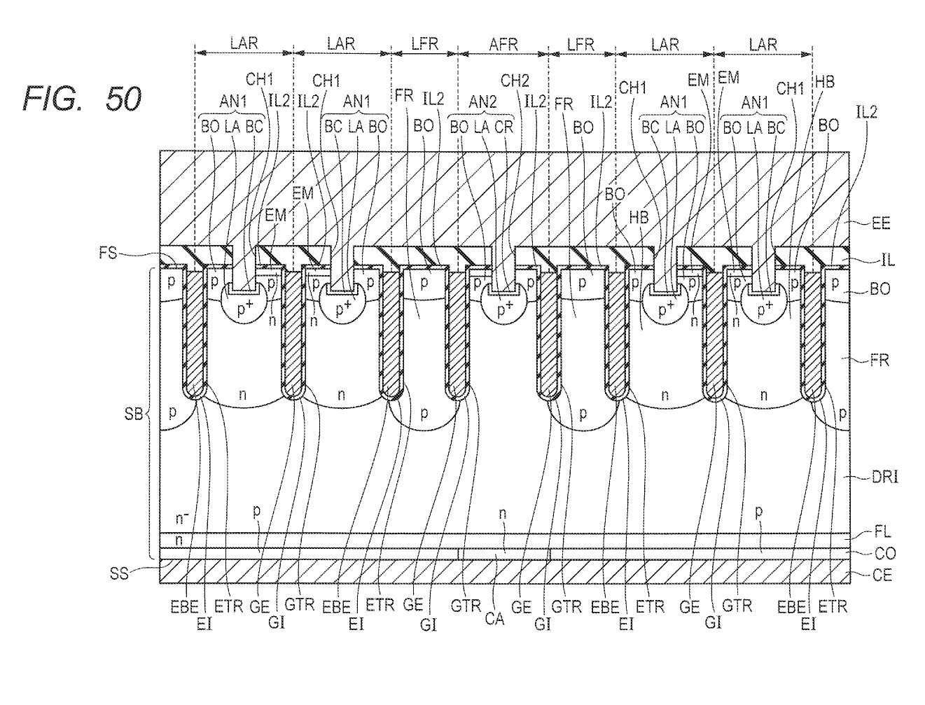

In the first embodiment, as shown in FIG. 4, the anode formation region AFR is surrounded by the emitter groove ETR. The anode formation region AFR may be surrounded by the gate groove GTR as will be discussed in a first modification shown in FIGS. 49 and 50.

As shown in FIGS. 49 and 50, in the configuration of the present modification, the anode formation region AFR is surrounded by the gate groove GTR. The gate insulating layer GI is formed on the inner wall of the gate groove GTR surrounding the anode formation region. The gate groove GTR is filled with the gate electrode GE. The anode region AN2 of the anode formation region AFR is in contact with the gate groove GTR.

In the configuration of FIG. 49, the anode formation region AFR and the linear active region LAR are adjacent to each other.

In the configuration of FIG. 50, the anode formation region AFR and the linear floating region LFR are adjacent to each other.

Other configurations of the present modification are substantially identical to those of the first embodiment shown in FIGS. 2 to 5.

Thus, the same elements as those of the first embodiment are indicated by the same symbols in the present modification and the explanation thereof will not be repeated. Also in this configuration, the same effect can be obtained as in the first embodiment.

### Second Modification

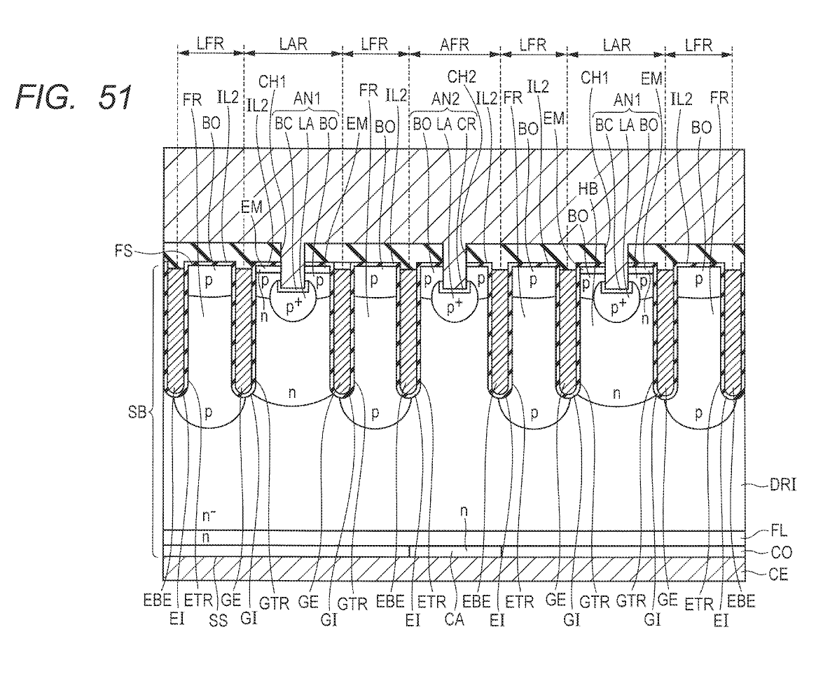

In the first embodiment, as shown in FIG. 4, the gate groove GTR is arranged in a region interposed between the two linear active regions LAR in plan view. As in a second modification shown in FIG. 51, two pairs of gate grooves GTR may be formed in plan view so as to surround the single linear active region LAR. The n-type emitter region EM is arranged over a region coupled to the pair of gate grooves GTR on the first major surface FS. The n-type emitter region EM includes a pn junction with the p-type body region BO.

Other configurations of the present modification are substantially identical to those of the first embodiment shown in FIGS. 2 to 5. Thus, the same elements as those of the first embodiment are indicated by the same symbols in the present modification and the explanation thereof will not be repeated. Also in this configuration, the same effect can be obtained as in the first embodiment.

In the first and second embodiments and the improvement examples thereof, the emitter of the IGBT has n-type conductivity and the collector of the IGBT has p-type conductivity. The same effect can be obtained even if the emitter of the IGBT has p-type conductivity and the collector of the IGBT has n-type conductivity.

### (Electronic System)

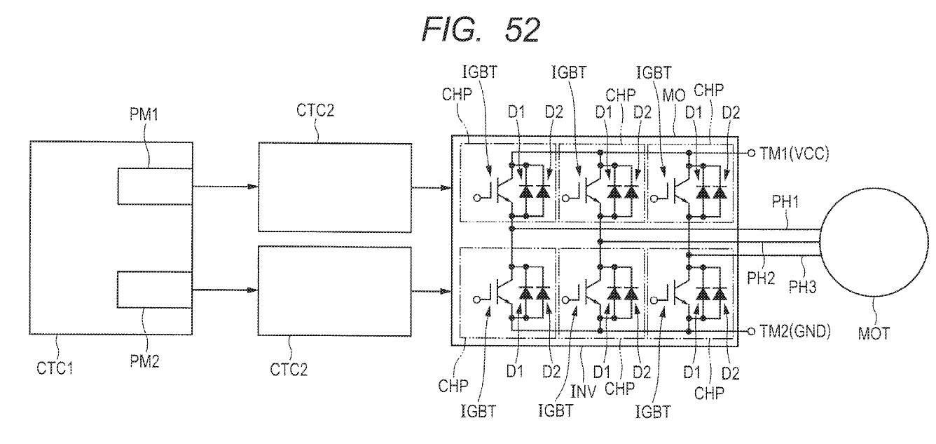

The semiconductor devices illustrated in the first embodiment and the improvement examples thereof, the second embodiment and the improvement examples thereof, and the modifications are used for, for example, an electronic system shown in FIG. 52.

As shown in FIG. 52, the system includes, for example, a semiconductor module MO, control circuits CTC1 and CTC2, and a motor MOT serving as a load.

For example, the control circuit CTC1 is electrically coupled to the two control circuits CTC2. The two control circuits CTC2 are each electrically coupled to the semiconductor module MO. The semiconductor module MO is electrically coupled to the motor MOT.

In this electronic system, the semiconductor module is, for example, an inverter INV. The inverter INV has input terminals TM1 and TM2 that are coupled to, for example, the output of a power generation module (not shown). Thus, the direct-current voltage, that is, direct-current power of the power generation module is supplied to the inverter INV.

The control circuit CTC1 includes, for example, an electronic control unit (ECU). The control circuit CTC1 contains a control semiconductor chip, e.g., a micro controller unit (MCU). The control circuit CTC1 includes a plurality of power modules PM1 and PM2. Each of the power modules PM1 and PM2 also includes an ECU and contains a control semiconductor chip, e.g., a MCU.

The power modules PM1 and PM2 included in the control circuit CTC1 are each coupled to a control circuit CTC2. The inverter INV is controlled by the control circuit CTC2. The control circuit CTC2 includes, for example, a gate driver and a photocoupler, which are not shown. The gate driver (not shown) included in the control circuit CTC2 is coupled to the inverter INV. At this point, the gate driver (not shown) included in the control circuit CTC2 is coupled to the gate electrode of an IGBT provided in the inverter INV.

The motor MOT is coupled to the inverter INV. A direct-current voltage supplied to the inverter INV from the power generation module (not shown), that is, direct-current power is converted to an alternating voltage, that is, direct-current power in the inverter INV and then is supplied to the motor MOT. The motor MOT is driven by the alternating voltage supplied from the inverter INV, that is, alternating-current power.

The motor MOT is a three-phase motor for a U phase PH1, a V phase PH2, and a W phase PH3. Thus, the inverter INV is also provided for three phases: the U phase PH1, the V phase PH2, and the W phase PH3. The inverter INV provided for the three phases has six semiconductor chips CHP. The six semiconductor chips CHP are semiconductor devices (semiconductor chips) according to one of the first embodiment and the improvement examples thereof, the second embodiment and the improvement examples thereof, and the modifications. The semiconductor chip CHP includes an RC-IGBT.

The invention made by the present inventors was specifically described according to the foregoing embodiments. Obviously, the present invention is not limited to the foregoing embodiments and can be changed in various ways within the scope of the invention.

What is claimed is:

1. A semiconductor device comprising:
a semiconductor substrate having a first major surface, a second major surface opposite from the first major surface, and an emitter groove surrounding an anode formation region on the first major surface;
an emitter groove electrode embedded in the emitter groove;
an insulating gate bipolar transistor having a body region of a first conductivity type over the semiconductor substrate, an emitter region of a second conductivity type, the emitter region being arranged over the body region and near the first major surface so as to be electrically coupled to the emitter groove electrode, and a collector region of the first conductivity type, the collector region being arranged over the body region and near the second major surface;
a first diode having a first anode region of the first conductivity type, the first anode region including the same impurity region as the body region;
a second diode having a second anode region of the first conductivity type, the second anode region being arranged over the anode formation region so as to be separated from the first anode region by the emitter groove;
a cathode region of the second conductivity type, the cathode region being arranged over the second major surface so as to act as a cathode for each of the first diode and the second diode, and
a first electrode that is arranged over the second major surface and is in contact with the collector region and the cathode region.

2. The semiconductor device according to claim 1, further comprising a second electrode that is arranged over the first major surface and is electrically coupled to each of the emitter region, the first anode region, and the second anode region.

3. The semiconductor device according to claim 2, further comprising an insulating layer arranged over the first major surface,
wherein the insulating layer has a hole reaching the second anode region, and
wherein the second electrode is in contact with the second anode region through the hole.

4. The semiconductor device according to claim 3,
wherein the hole only includes a single hole part formed over the anode formation region.

5. The semiconductor device according to claim 3,
wherein the hole includes a plurality of hole parts formed over the anode formation region.

6. The semiconductor device according to claim 1, further comprising a drift region of the second conductivity type, the drift region being arranged between the body region and the collector region.

7. The semiconductor device according to claim 6,
wherein the drift region and the second anode region include a pn junction.

8. The semiconductor device according to claim 6, further comprising a barrier region of the second conductivity type, the barrier region being arranged between the drift region and the second anode region and having a higher impurity concentration than the drift region.

9. The semiconductor device according to claim 1,
wherein the semiconductor substrate has a gate groove over the first major surface, and
wherein the insulating gate bipolar transistor includes a gate electrode arranged in the gate groove,
the gate groove including, in plan view, a first gate groove part and a second gate groove part with the anode formation region interposed between the first and second groove parts in a first direction, and a third gate groove part and a fourth gate groove part with the anode formation region interposed between the third and fourth gate groove parts in a second direction orthogonal to the first direction.

10. The semiconductor device according to claim 9, further comprising an insulating layer arranged over the first major surface,
wherein the insulating layer has a first hole part reaching the first anode region, a second hole part reaching the second anode region, and a third hole part reaching the emitter groove electrode, and
wherein the first hole part, the second hole part, and the third hole part are separated from one another.

11. The semiconductor device according to claim 9, further comprising an insulating layer arranged over the first major surface,
wherein the insulating layer has a first hole part reaching both of the first anode region and the emitter groove electrode and a second hole part reaching the second anode region, and
wherein the first hole part and the second hole part are separated from each other.

12. The semiconductor device according to claim 9, further comprising an insulating layer arranged over the first major surface,
wherein insulating layer has a hole part that reaches all of the first anode region, the second anode region, and the emitter groove electrode.

13. The semiconductor device according to claim 12,
wherein the hole part is arranged so as to be laid over a plane region in plan view, the plane region being a combination of the overall anode formation region, the overall emitter groove surrounding the anode formation region, and a part of the first anode region surrounding an outer edge of the emitter groove.

14. The semiconductor device according to claim 12,
wherein the hole part is arranged across a part of a plane region in plan view, the plane region being a combination of the anode formation region, the emitter groove surrounding the anode formation region, and the first anode region surrounding an outer edge of the emitter groove.

15. A semiconductor device comprising:
a semiconductor substrate having a first major surface, a second major surface opposite from the first major surface, and a gate groove surrounding an anode formation region over the first major surface;
an insulating gate bipolar transistor having a body region of a first conductivity type over the semiconductor substrate, an emitter region of a second conductivity type, the emitter region being arranged over the body region and near the first major surface, a collector region of the first conductivity type, the collector region being arranged over the body region and near the second major surface, and a gate electrode embedded in the gate groove;
a first diode having a first anode region of the first conductivity type, the first anode region including the same impurity region as the body region;
a second diode having a second anode region of the first conductivity type, the second anode region being arranged over the anode formation region so as to be separated from the first anode region by the gate groove;
a cathode region of the second conductivity type, the cathode region being arranged over the second major surface so as to act as a cathode for each of the first diode and the second diode; and
a first electrode that is arranged over the second major surface and is in contact with the collector region and the cathode region.

16. A method of manufacturing a semiconductor device, comprising the steps of:
preparing a semiconductor substrate having a first major surface, a second major surface opposite from the first major surface, and an emitter groove surrounding an anode formation region over the first major surface;
forming an emitter groove electrode embedded in the emitter groove;
forming an insulating gate bipolar transistor having a body region of a first conductivity type over the semiconductor substrate, an emitter region of a second conductivity type, the emitter region being arranged over the body region and near the first major surface so as to be electrically coupled to the emitter groove electrode, and a collector region of the first conductivity type, the collector region being arranged over the body region and near the second major surface;
forming a first anode region of the first conductivity type, the first anode region including the same impurity region as the body region;
forming a second anode region of the first conductivity type, the second anode region being arranged over the anode formation region so as to be separated from the first anode region by the emitter groove;
forming a cathode region of the second conductivity type, the cathode region being arranged over the second major surface so as to include a first diode with the first anode region and include a second diode with the second anode region; and
forming an electrode that is arranged over the second major surface and is in contact with the collector region and the cathode region.
